(19) United States
(12) Patent Application Publication
(10) Pub. No.: US 2025/0180613 A1
(43) Pub. Date: Jun. 5, 2025

(54) REAL TIME LIVE LINE MEASUREMENT OF CURRENT AND VOLTAGE TRANSFORMERS

(71) Applicants: Uros KOVACEVIC, Belgrade (RS); Vladeta MILENKOVIC, Niš (RS)

(72) Inventors: Uros KOVACEVIC, Belgrade (RS); Vladeta MILENKOVIC, Niš (RS)

(21) Appl. No.: 18/840,690

(22) PCT Filed: Feb. 27, 2023
(86) PCT No.: PCT/EP2023/054870

§ 371 Date: Aug. 22, 2024

(30) Foreign Application Priority Data
Feb. 28, 2022 (GB) 2202741.1

(51) Int. Cl. G01R 21/133

(52) U.S. Cl. CPC G01R 21/1331

(57) ABSTRACT

A real-time live line method analyses properties of an electricity substation. The method uses an upstream current sensor and an upstream voltage sensor to obtain a series of upstream current data points and a series of upstream voltage data points during a first time period and attributes respective GNSS time stamps provided by a first and a second GNSS signal receiver to the data points. The method uses a downstream current sensor and a downstream voltage sensor to obtain a series of downstream current data points and a series of downstream voltage data points during the first time period and attributes respective GNSS time stamps provided by a third and a fourth GNSS signal receiver to the data points. The method calculates a current transformer phase displacement error, a current transformer ratio error, a voltage transformer phase displacement error, and a voltage transformer ratio error. The method also calculates upstream active and reactive power data and calculates downstream active and reactive power data.

### CROSS-REFERENCE TO RELATED APPLICATION

This application is a national stage of International Application No. PCT/EP2023/054870, filed on Feb. 27, 2023, which claims priority to United Kingdom Application No. 2202741.1, filed on Feb. 28, 2022, both of the aforementioned applications are hereby incorporated by reference in their entireties.

### FIELD OF THE DISCLOSURE

A method and associated apparatus for obtaining real time live line measurement of metrological properties of voltage and current transformers is disclosed. Also disclosed is a method of using those real time live line measurements to determine the components of errors in the measurement of electrical power and energy caused by current transformers, voltage transformers and energy meters.

### BACKGROUND

Current and voltage transformers play a key function in electricity transmission and distribution networks.

Electricity may be transferred from a power station at so-called extra high voltage (often higher than 400 kV). Electricity may be transferred to industrial power plants and other energy intensive facilities at so-called high voltage (at least 110 kV). Electricity may be distributed to city networks at so-called medium voltage (lower than 110 kV and higher than 10 kV) and to consumers at domestic voltage (110 V or 230 V). Currents flowing through the transmission and distribution network can be from several hundred Amps to several thousand Amps.

Thus, electricity networks use a range of instrument transformers, both for transforming voltage and for transforming current.

Current and voltage transformers may be provided with a rating that defines the transformation performed by the instrument transformer. The metrology performance of the instrument transformer may deteriorate with time relative to the nominal rating.

When dealing with high wattages, small deviations in the actual rating of an instrument transformer may have a significant impact on the measurement uncertainty in the measurement of power and energy. This directly affects the accuracy of measurement and billing of electrical power and energy.

It is known to make live line measurements of an electricity meter to determine errors in active and reactive power arising from an imperfect electricity meter. However, errors in active and reactive power resulting from an imperfect electricity meter may be modest compared to errors in active and reactive power resulting from voltage and current transformers.

It is therefore helpful to be able to make live line measurements of voltages and currents when an instrument transformer is in use and to calculate errors in the measurement of electric power and energy. Such an approach enables transformers to be tested without taking them offline.

### SUMMARY OF THE DISCLOSURE

Against this background, there is provided a system for undertaking real time live line measurement of properties of current and voltage transformer assemblies. This also enables determining errors between an expected amount of power and energy transfer and an actual amount of power and energy transfer.

In particular, in a first aspect of the disclosure there is provided an online live line method of analysing properties of an electricity substation comprising a current transformer and a voltage transformer, the electricity substation configured to transform an upstream current and an upstream voltage into a downstream current and a downstream voltage, the method comprising:
using an upstream current sensor to obtain a series of upstream current data points during a first time period and attributing a time stamp provided by a first global navigation satellite system (GNSS) signal receiver to each one of the series of upstream current data points;
using a downstream current sensor to obtain a series of downstream current data points during the first time period and attributing a time stamp provided by a second GNSS signal receiver to each one of the series of downstream current data points;
using an upstream voltage sensor to obtain a series of upstream voltage data points during the first time period and attributing a time stamp provided by a third GNSS signal receiver to each one of the series of upstream voltage data points;
using a downstream voltage sensor to obtain a series of downstream voltage data points during the first time period and attributing a time stamp provided by a fourth GNSS signal receiver to each one of the series of upstream current data points;
calculating a current transformer phase displacement error between the time-stamped series of upstream current data points and the time-stamped series of downstream current data points;
calculating a current transformer ratio error by comparing a rated current ratio of the current transformer with a measured ratio determined using the time-stamped series of upstream current data points and the time-stamped series of downstream current data points;
calculating a voltage transformer phase displacement error between the time-stamped series of upstream voltage data points and the time-stamped series of downstream voltage data points;
calculating a voltage transformer ratio error by comparing a rated voltage ratio of the voltage transformer with a measured voltage ratio determined using the time-stamped series of upstream voltage data points and the time-stamped series of downstream voltage data points;
using the time-stamped series of upstream current data points and the time-stamped series of upstream voltage data points to produce calculated upstream active and reactive power data;
using the time-stamped series of downstream current data points and the time-stamped series of downstream voltage data points to produce calculated downstream active and reactive power data.

In this way, the method enables real time live line determination of the components of errors in the measurement of electrical power and energy caused by current transformers, voltage transformers and energy meters.

Optionally, the method may comprise using:
the calculated current transformer phase displacement error; and
the calculated current transformer ratio error;
to calculate an error of active and reactive power measurement resulting from the current transformer.

Optionally, the method may comprise using:
the calculated voltage transformer phase displacement error; and
the calculated voltage transformer ratio error;
to calculate an error of active and reactive power measurement resulting from the voltage transformer.

Optionally, the method may comprise comprising obtaining measured active and reactive power data from an electricity meter downstream of the electricity substation configured for metering power supplied by the substation.

Optionally, the method may comprise using:
the calculated upstream active and reactive power data; and
the active and reactive power data from the downstream electricity meter;
to calculate a total error of active and reactive power measurement.

Optionally, the method may comprise using:
the calculated downstream active and reactive power data; and
the active and reactive power data from the downstream electricity meter;
to calculate an error component in active and reactive power measurement by the downstream electricity meter.

In this way, errors in actual active and reactive energy versus expected active and reactive energy may be quantified. Consequently, errors in energy cost calculation may be used to correct billing inaccuracies.

Optionally, the method may further comprise a calibration process carried out to quantify upstream current sensor errors, downstream current sensor errors, upstream voltage sensor errors and downstream voltage sensor errors.

Optionally:
time-stamped series of upstream current data points are adapted to compensate for the upstream current sensor errors;
time-stamped series of downstream current data points are adapted to compensate for the downstream current sensor errors;
time-stamped series of upstream voltage data points are adapted to compensate for the upstream voltage sensor errors; and
time-stamped series of downstream voltage data points are adapted to compensate for the downstream voltage sensor errors.

Optionally, the measured ratio is a ratio of:
a root mean square value of the series of upstream data points; to
a root mean square value of the series of downstream data points.

Optionally, the current/voltage transformer phase displacement error is proportional to a time difference between at least one pair of successive zero crossings of time stamped upstream data and time stamped downstream data, wherein accuracy of time reference is less than 100 nanoseconds and preferably approximately 10 nanoseconds.

Optionally, each of the stream of upstream current or voltage data points and the stream of downstream current or voltage data points comprises at least 20,000 data points per AC cycle, preferably 40,000 data points per AC cycle.

Optionally, the electric substation may be a three phase electric substation;
wherein the current transformer and the voltage transformer are a first phase current transformer and a first phase voltage transformer;
wherein the three phase electric substation comprises a second phase current transformer, a second phase voltage transformer, a third phase current transformer and a third phase voltage transformer;
wherein the method comprises deploying the method set out for a single phase on each of the three phases.

Optionally, the deployment of the method for three phases is carried out on each of the three phases simultaneously.

Optionally, the method comprises one or both of:
using the calculated upstream active and reactive power data to calculate upstream active and reactive energy data;
using the calculated downstream active and reactive power data to calculate downstream active and reactive energy data.

In a second aspect of the disclosure, there is provided a kit of parts for carrying out the method, the kit of parts comprising:
an upstream current sensor module comprising an upstream current sensor and a first global navigation satellite system (GNSS) signal receiver, wherein the upstream current sensor is configured to obtain a series of upstream current data points during a first time period and the first GNSS signal receiver is configured to attribute a time stamp to each one of the series of upstream current data points;
a downstream current sensor module comprising a downstream current sensor and a second GNSS signal receiver, wherein the downstream current sensor is configured to obtain a series of downstream current data points during a first time period and the second GNSS signal receiver is configured to attribute a time stamp to each one of the series of downstream current data points;
an upstream voltage sensor module comprising an upstream voltage sensor and a first global navigation satellite system (GNSS) signal receiver, wherein the upstream voltage sensor is configured to obtain a series of upstream voltage data points during a first time period and the first GNSS signal receiver is configured to attribute a time stamp to each one of the series of upstream voltage data points;
a downstream voltage sensor module comprising a downstream voltage sensor and a second GNSS signal receiver, wherein the downstream voltage sensor is configured to obtain a series of downstream voltage data points during a first time period and the second GNSS signal receiver is configured to attribute a time stamp to each one of the series of downstream voltage data points.

In this way, real time live line determination of the components of errors in the measurement of electrical power and energy caused by current transformers, voltage transformers and energy meters is enabled.

Optionally:
the upstream current sensor module further comprises an upstream current measuring unit configured to digitize the series of upstream current data points;
the downstream current sensor module further comprises a downstream current measuring unit configured to digitize the series of downstream current data points;
the upstream voltage sensor module further comprises an upstream voltage measuring unit configured to digitize the series of upstream voltage data points;
the downstream voltage sensor module further comprises a downstream voltage measuring unit configured to digitize the series of downstream voltage data points.

Optionally, each of the upstream current sensor module, the downstream current sensor module, the upstream voltage sensor module and the downstream voltage sensor module comprises wireless communication functionality for receiving instructions pertaining to a measurement to be performed and for transmitting the time stamped series of data points for onward processing.

Optionally, one of the upstream current sensor module and the downstream current sensor module receives the time stamped current data provided by the other of the upstream current sensor module and the downstream current sensor module and is configured:
to calculate a current transformer phase displacement error between the time-stamped series of upstream current data points and the time-stamped series of downstream current data points; and
to calculate a current transformer ratio error by comparing a rated current ratio of the current transformer with a measured ratio determined using the time-stamped series of upstream current data points and the time-stamped series of downstream current data points.

Optionally, one of the upstream voltage sensor module and the downstream voltage sensor module receives the time stamped voltage data provided by the other of the upstream voltage sensor module and the downstream voltage sensor module and is configured:
to calculate a voltage transformer phase displacement error between the time-stamped series of upstream voltage data points and the time-stamped series of downstream voltage data points; and
to calculate a voltage transformer ratio error by comparing a rated current ratio of the voltage transformer with a measured ratio determined using the time-stamped series of upstream voltage data points and the time-stamped series of downstream voltage data points.

Optionally, the kit of parts further comprises a processor configured to receive:
the time stamped current data provided by the upstream current sensor module;
the time stamped current data provided by the downstream current sensor module;
the time stamped voltage data provided by the upstream voltage sensor module; and
the time stamped voltage data provided by the downstream voltage sensor module; and is configured to:
calculate a current transformer phase displacement error between the time-stamped series of upstream current data points and the time-stamped series of downstream current data points; and to
calculate a current transformer ratio error by comparing a rated current ratio of the current transformer with a measured current ratio determined using the time-stamped series of upstream current data points and the time-stamped series of downstream current data points;
calculate a voltage transformer phase displacement error between the time-stamped series of upstream voltage data points and the time-stamped series of downstream voltage data points; and to
calculate a voltage transformer ratio error by comparing a rated voltage ratio of the voltage transformer with a measured voltage ratio determined using the time-stamped series of upstream voltage data points and the time-stamped series of downstream voltage data points.

Optionally, the processor is further configured to:
use the time-stamped series of upstream current data points and the time-stamped series of upstream voltage data points to produce calculated upstream active and reactive power data;
use the time-stamped series of downstream current data points and the time-stamped series of downstream voltage data points to produce calculated downstream active and reactive power data.

Optionally, the processor is further configured to use the calculated current transformer phase displacement error and the calculated current transformer ratio error to calculate an error of active and reactive power measurement resulting from the current transformer.

Optionally, the processor is further configured to use the calculated voltage transformer phase displacement error and the calculated voltage transformer ratio error to calculate an error of active and reactive power measurement resulting from the voltage transformer.

Optionally, the processor is further configured to obtain measured active and reactive power data from an electricity meter downstream of the electricity substation configured for metering power supplied by the substation.

Optionally, the processor is further configured to use the calculated upstream active and reactive power data and the active and reactive power data from the downstream electricity meter to calculate a total error of active and reactive power measurement and, optionally, wherein the processor is further configured to use the calculated downstream active and reactive power data and the active and reactive power data from the downstream electricity meter to calculate an error component in active and reactive power measurement by the downstream electricity meter.

Optionally, the processor is further configured to compensate for known errors in the measurements provided by the upstream current sensor module, the downstream current sensor module, the upstream voltage sensor module and the downstream voltage sensor module.

### BRIEF DESCRIPTION OF THE DRAWINGS

Embodiments of the disclosure are now described with reference to the following figures:

FIG. 1 shows a schematic representation of part of an electricity transmission/distribution network including a current transformer and a voltage transformer;

FIG. 2 shows a schematic representation of a current transformer together with apparatus for measuring the current transformer in accordance with the present disclosure;

FIG. 3 shows a schematic representation of a voltage transformer together with apparatus for measuring the voltage transformer in accordance with the present disclosure;

FIG. 4 shows the primary current sensor module, the secondary current sensor module, the primary voltage sensor module and the secondary voltage sensor module in situ measuring a current transformer and a voltage transformer;

FIG. 5 shows a high level flow chart showing aspects of the method of the disclosure for measuring either a current transformer or a voltage transformer;

FIG. 6 shows in more detail the measurement cell of the flow chart of FIG. 5 when applied to the measurement of a current transformer;

FIG. 7 shows in more detail the measurement cell of the flow chart of FIG. 5 when applied to the measurement of a voltage transformer;

FIG. 8 shows a schematic representation of the use of the data determined from the primary current sensor module, the secondary current sensor module, the primary voltage sensor module and the secondary voltage sensor module to determine current transformer, voltage transformer and energy meter accuracy;

FIG. 9 presents schematically the data used to calculate power errors at the high voltage side;

FIG. 10 presents schematically the data used to calculate current transformer errors;

FIG. 11 presents schematically the data used to calculate voltage transformer errors;

FIG. 12 presents schematically the data used to calculate power errors at the low voltage side;

FIG. 13 shows a schematic representation of an upstream/primary current sensor module in accordance with the present disclosure;

FIG. 14 shows a schematic representation of a downstream/secondary current sensor module in accordance with the present disclosure;

FIG. 15 shows a schematic representation of an upstream/primary voltage sensor module in accordance with the present disclosure;

FIG. 16 shows a schematic representation of a downstream/secondary voltage sensor module in accordance with the present disclosure;

FIG. 17 shows an edge gateway device;

FIG. 18 shows a simplified electrical scheme by which calibration data may be obtained for a pair of current sensor modules shown in FIGS. 13 and 14, where one of the pair is a primary current sensing module and the other of the pair is a secondary current sensing module;

FIG. 19 shows a simplified electrical scheme by which calibration data may be obtained for a pair of voltage sensor modules shown in FIGS. 15 and 16, where one of the pair is a primary voltage sensing module and the other of the pair is a secondary voltage sensing module;

FIGS. 20a and 20b show examples of the use of linear interpolation for precise determination of results data for current sensing modules;

FIGS. 21a and 21b show examples of the use of linear interpolation for precise determination of results data for voltage sensing modules; and

FIG. 22 shows a schematic representation of the deployment of the method of the disclosure in the context of a three phase system.

### DETAILED DESCRIPTION

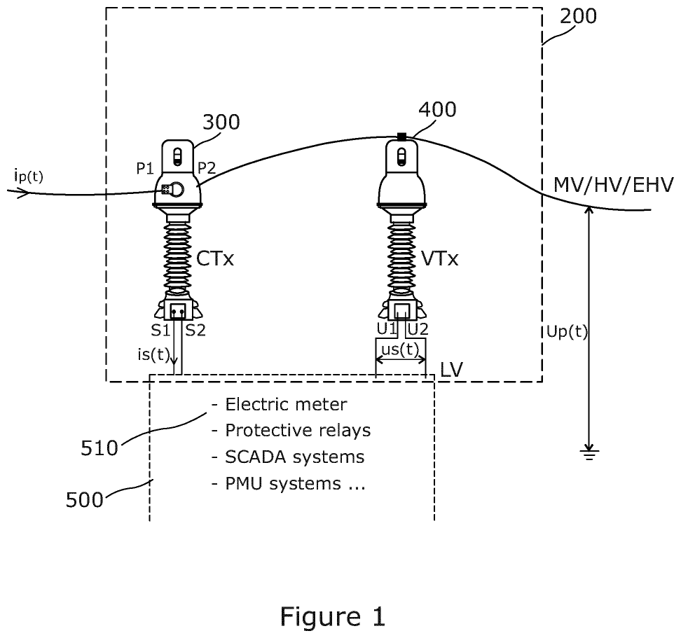

FIG. 1 shows a schematic representation of part of an electricity transmission or distribution network including a current transformer (CTx) 300 and a voltage transformer, (VTx) 400. The electricity transmission or distribution network may operate at medium voltage (MV), high voltage (HV) or extra high voltage (EHV).

The upstream conductor may be part of a longer distance power network at a medium or high voltage and high current. The downstream conductor may be for local supply, a shorter distance at low voltage and at a lower current, such as in the context of power meters, protective relays, SCADA systems, PMU system. The high voltage may be of the order of between 1 kV and 1,000 s of kV. The low voltage may be of the order of 100 V, 100/√3 V, 110 V, 110/√3 V, 200 V, 200/√3 V or similar. Currents flowing through the transmission/distribution network can be from several hundred Amps to several thousand Amps. Currents flowing through the low voltage network can be 1 Amps to 5 Amps.

The method of the present disclosure is equally applicable to a scenario where the upstream conductor is at a lower voltage than the downstream conductor. However, the examples set out here are based on the upstream conductor being at a higher voltage than the downstream conductor.

The current transformer 300 and the voltage transformer 400 may together form an electricity substation 200 for supplying a downstream electricity network 500. The downstream electricity network 500 may comprise an electricity meter 510.

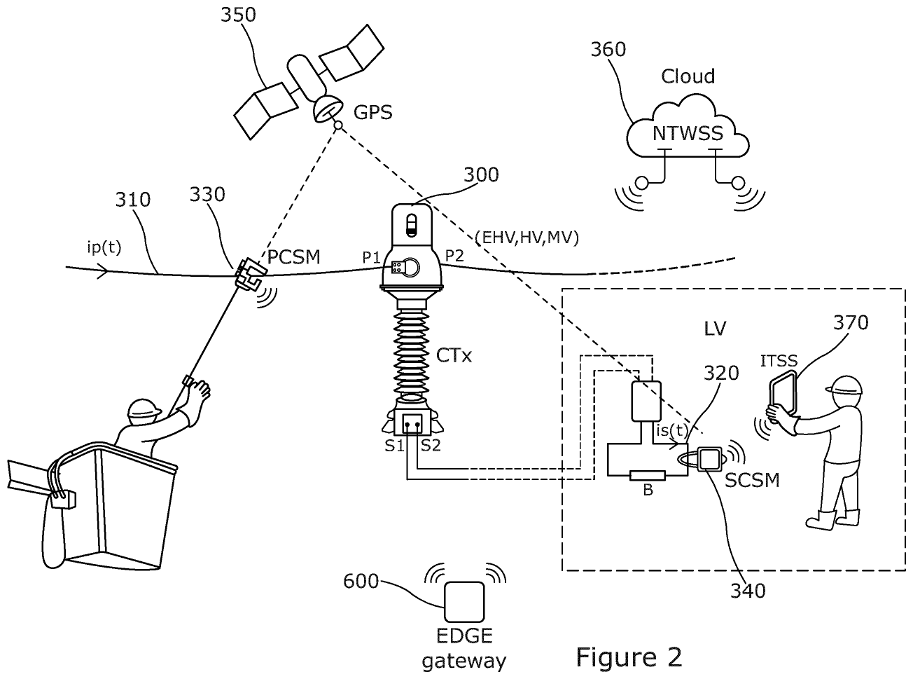

FIG. 2 shows a schematic representation of a current transformer 300 (in isolation from a voltage transformer 400) together with apparatus for measuring the current transformer.

In the FIG. 2 arrangement, the current transformer 300 under test may be configured to transform an upstream current in an upstream conductor 310 (that may be part of a longer distance power network at a higher current and at a medium or high voltage) into a downstream current in a downstream conductor 320 (for local supply a shorter distance at a lower current and at low voltage, such as in the context of power meters, protective relays, SCADA systems, PMU system).

An upstream sensing module 330 (also termed a primary sensing module) is located to sense the upstream conductor 310. A downstream sensing module 340 (also termed a secondary sensing module) is located to sense the downstream conductor 320.

A signal from a GNSS (such as a GPS 350) is received, separately, by the upstream sensing module 330 and the downstream sensing module 340. In this way, the current data values sensed by the upstream sensing module 330 and by the downstream sensing module 340 are each attributed a highly accurate time stamp provided by the GNSS signal.

The time-stamped upstream current data values from the upstream current sensing module 330 may be transmitted to the secondary current sensing module 340. Alternatively, the time-stamped upstream current data values and the time-stamped downstream current data values may be transmitted to a separate processor (e.g. labelled an edge gateway device 600) or to a mobile device 370 or to a cloud server 360. In any case, the time-stamped upstream current data values and the time-stamped downstream current data values are aggregated and used determine ratio and phase displacement errors between the upstream current and the downstream current.

The measured current ratio error may be a ratio of: a root mean square value of the series of upstream current data points to a root mean square value of the series of downstream current data points. Similarly, the measured voltage ratio error may be a ratio of: a root mean square value of the series of upstream voltage data points to a root mean square value of the series of downstream voltage data points.

The current transformer phase displacement error is proportional to a time difference between at least one pair of successive zero crossings of time stamped upstream current data and time stamped downstream current data. Accuracy of time reference may be less than 100 nanoseconds and preferably approximately 10 nanoseconds. Similarly, the voltage transformer phase displacement error is proportional to a time difference between at least one pair of successive zero crossings of time stamped upstream voltage data and time stamped downstream voltage data. Accuracy of time reference may be less than 100 nanoseconds and preferably approximately 10 nanoseconds.

Each of the stream of upstream current data points and the stream of downstream current data points comprises at least 20,000 data points per AC cycle, preferably 40,000 data points per AC cycle. Similarly, each of the stream of upstream voltage data points and the stream of downstream voltage data points comprises at least 20,000 data points per AC cycle, preferably 40,000 data points per AC cycle.

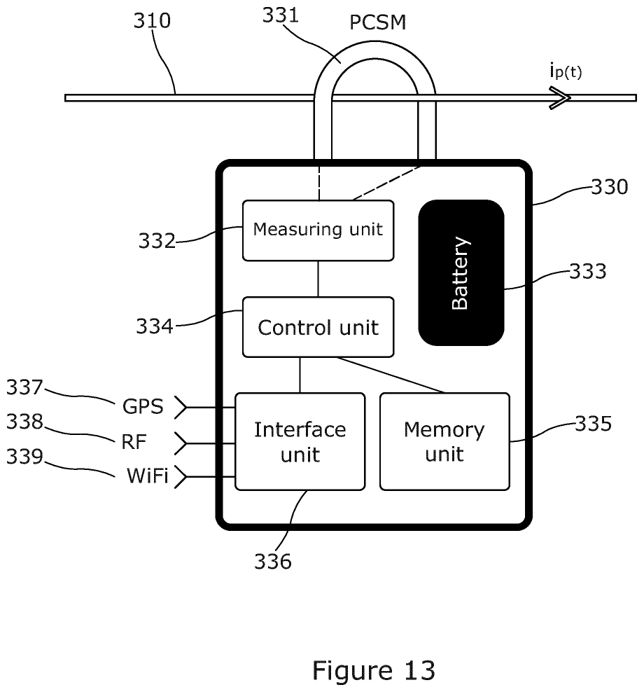

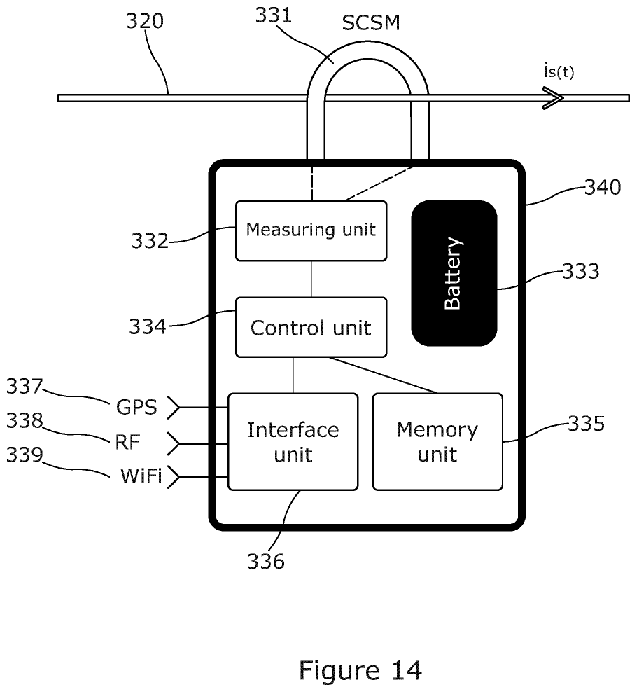

Example hardware that may be deployed for the upstream current sensing module and the downstream current sensing module is set out towards the end of this description and illustrated schematically in FIGS. 13 and 14, respectively, and is discussed in more detail later.

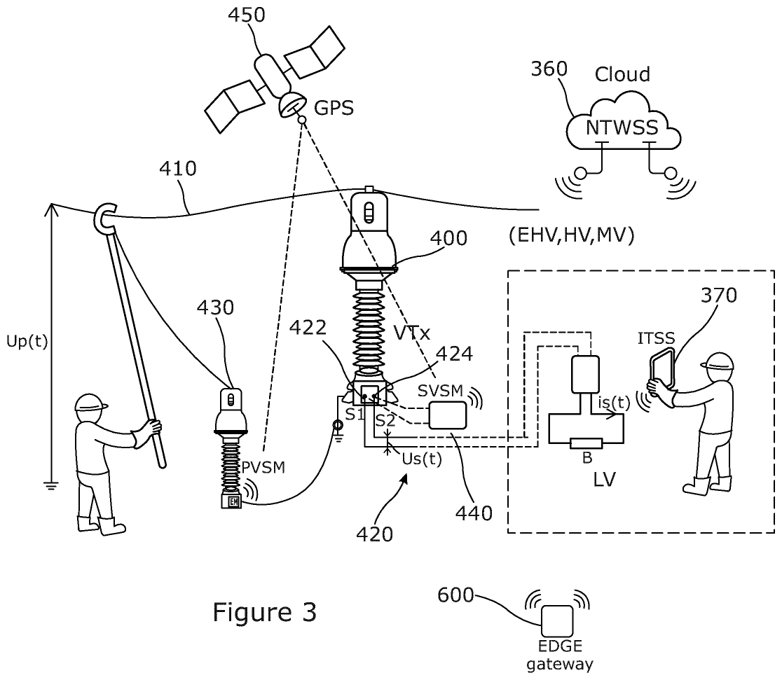

FIG. 3 shows a schematic representation of a voltage transformer 400 (in isolation from a current transformer 300) together with apparatus for measuring the voltage transformer.

In the FIG. 3 arrangement, the voltage transformer 400 under test is configured to transform an upstream voltage Up(t) (between an upstream conductor 410 and ground) into a downstream voltage Us(t) (between a first conductor 422 and a second conductor 424 forming a downstream circuit 420).

An upstream voltage sensing module 430 is attached between the upstream conductor 410 and ground. A downstream voltage sensing module 440 is attached between a first conductor 422 and a second conductor 424 forming a downstream circuit.

A signal from a GNSS (such as a GPS 450) is received, separately, by the upstream voltage sensing module 430 and the downstream voltage sensing module 440. In this way, the voltage data values sensed by the upstream voltage sensing module 430 and by the downstream voltage sensing module 440 are each attributed a highly accurate time stamp provided by the GNSS signal.

The time-stamped upstream voltage data values from the upstream voltage sensing module 430 may be transmitted to the downstream voltage sensing module 440. Alternatively, the time-stamped upstream voltage data values and the time-stamped downstream voltage data values may be transmitted to a separate processor (e.g. labelled an edge gateway device 600) or to a mobile device 370 or to a cloud server 360. In any case, the time-stamped upstream voltage data values and the time-stamped downstream voltage data values are aggregated and used determine ratio and phase displacement errors between the upstream voltage and the downstream voltage.

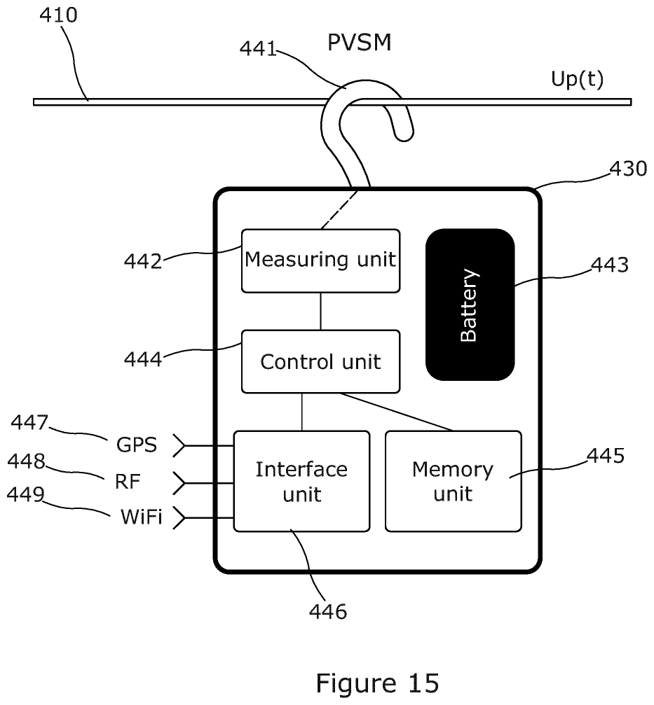

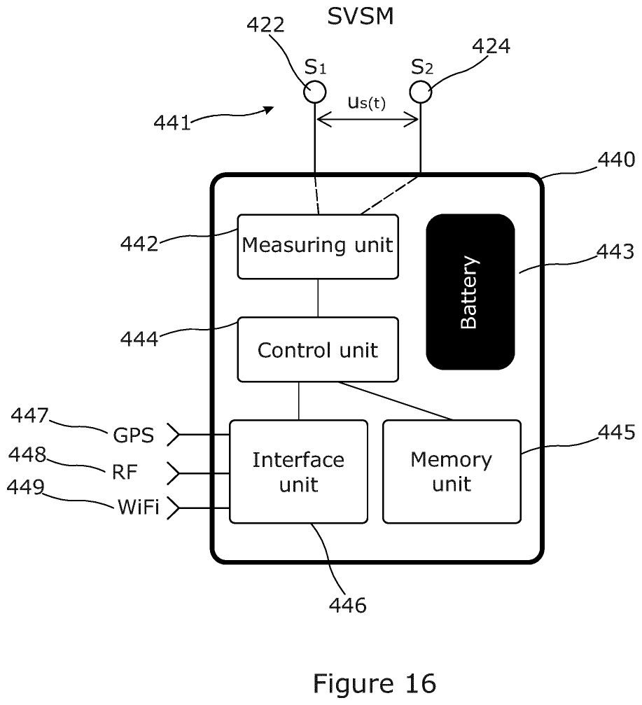

Example hardware that may be deployed for the upstream voltage sensing module and the downstream voltage sensing module is set out towards the end of this description and illustrated schematically in FIGS. 15 and 16, respectively, and is discussed in more detail later.

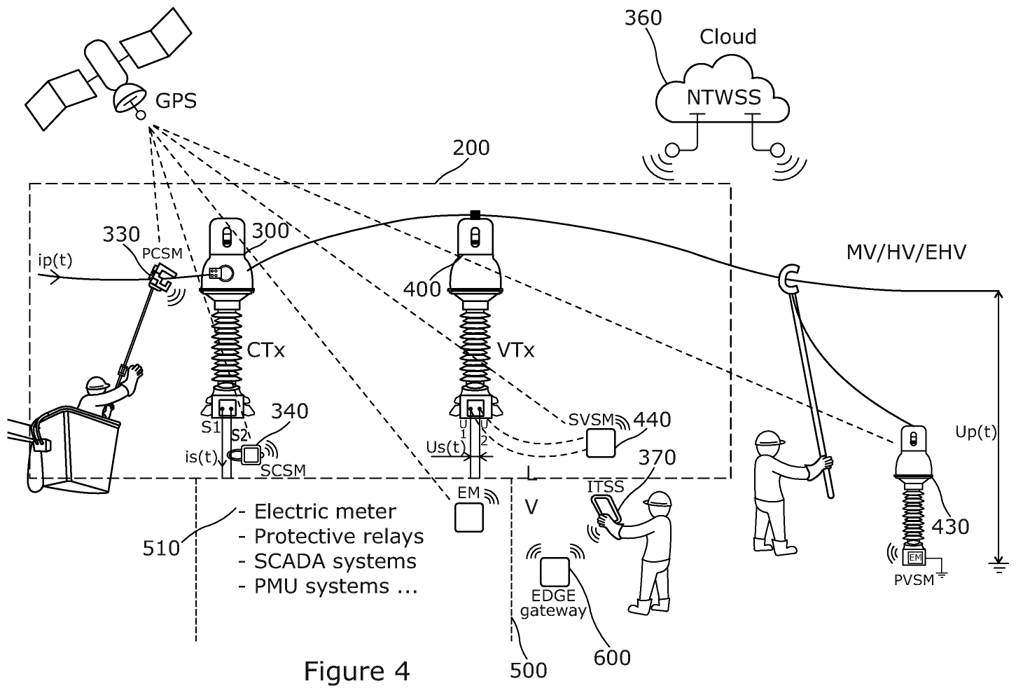

FIG. 4 shows an electricity substation 200 like that of FIG. 1 whilst undergoing the current transformer testing and voltage transformer testing.

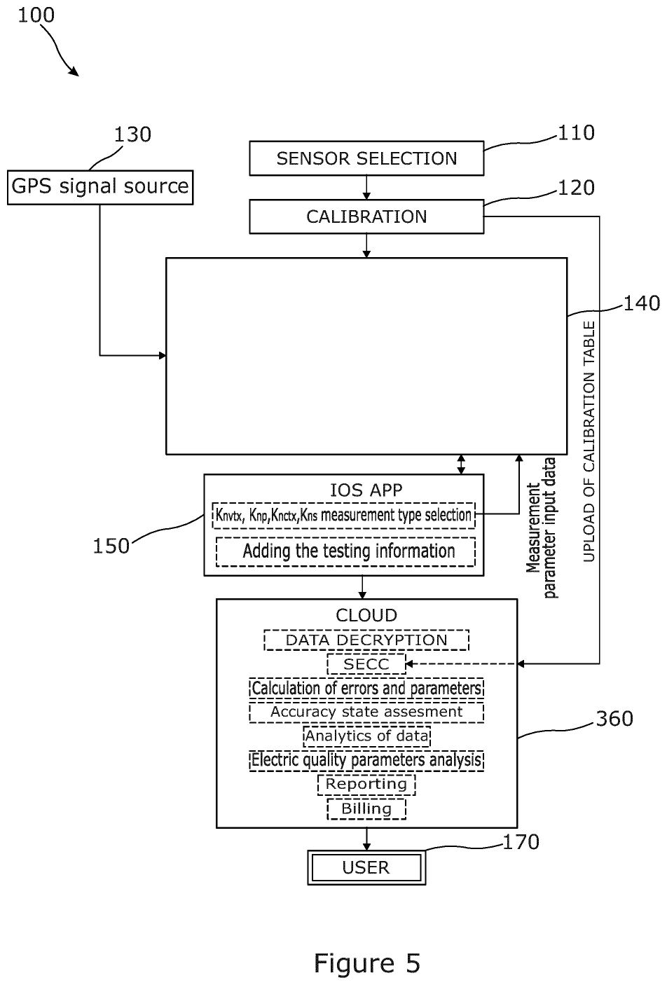

FIG. 5 shows a high level schematic representation of a method 100 carried out to measure properties of a current transformer 300 (FIG. 2) or a voltage transformer 400 (FIG. 3). The high level schematic representation of FIG. 5 may also be used as part of a method for an electricity substation 200 (FIGS. 1 and 4) to determine error components of electric power and energy caused by the current transformer 300, the voltage transformer 400 and an electric meter 510 configured to meter the electricity supply at the electricity substation.

The method 100 comprises a step of sensing module selection 110. In particular, it comprises selection of an appropriate upstream sensing module for sensing current/voltage in an upstream conductor that is upstream of the current/voltage transformer under test. It also comprises selection of an appropriate downstream sensing module for sensing current/voltage in a downstream conductor that is downstream of the current/voltage transformer under test. In each case the sensing module needs to be appropriate to the geometry of the relevant conductor and appropriate to the magnitude of the current being carried in the relevant conductor.

At step 120, a calibration process is performed. This is explained in more detail below. For some tests, it may be necessary for the calibration process to take place for the specific pair of sensing modules that have been selected. How frequently calibration is performed will depend on multiple factors.

At step 130 a signal is received from a global navigation satellite system (GNSS), such as a global positioning system (GPS™). The signal comprises highly accurate and precise time information which enables a precise and accurate time, to within 10 ns, to be attributed to events.

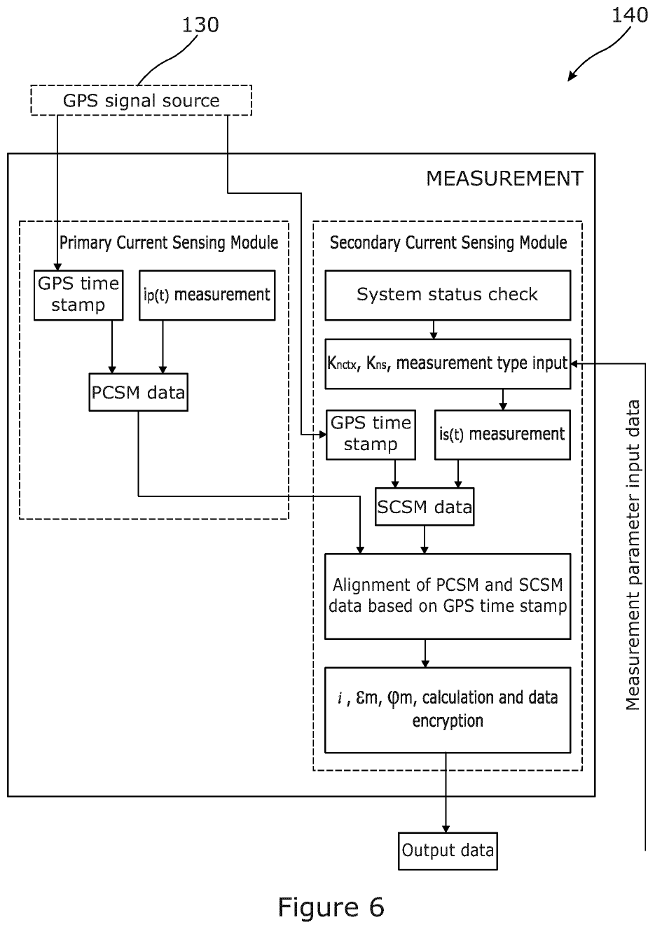

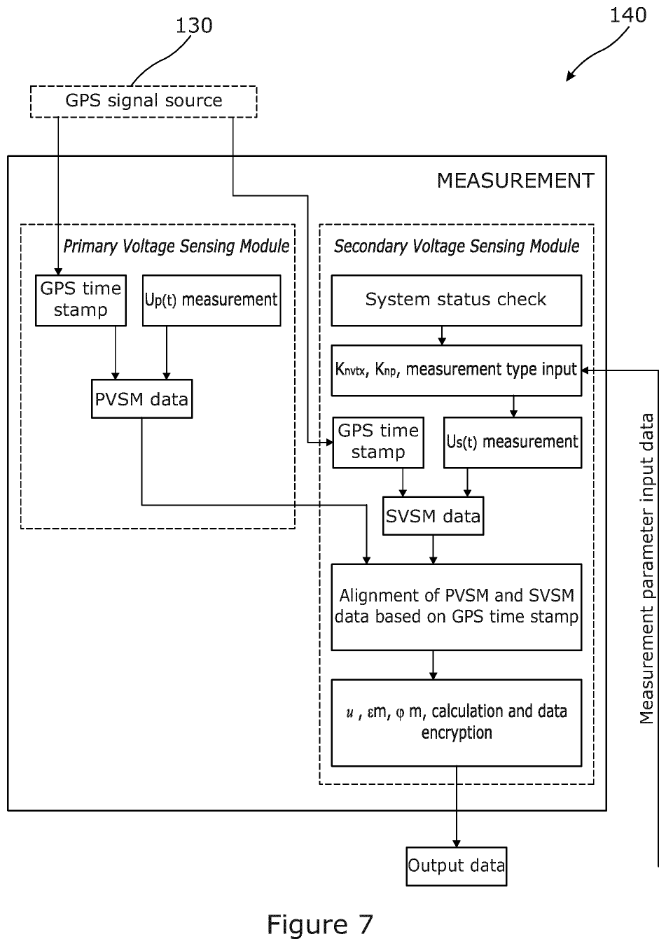

At step 140, measurement is performed by each of the two current/voltage sensing modules. The measurement steps are set out in more detail at FIG. 6 for current sensing and in FIG. 7 for voltage sensing. For each sensing module, a large number of current/voltage readings is taken and each reading is attributed a precise time stamp, as provided by the GNSS signal.

In a first option, one sensing module (either that configured to measure the upstream current/voltage or that configured to measure the downstream current/voltage) may be configured to transmit its time-stamped data points to the other sensing module. The sensing module that receives may then be configured to package the time-stamped data points from both the upstream and the downstream sensing modules and output the aggregated data.

In preferred implementations of the first option, the sensing module that receives and aggregates the data is the sensor configured to measure the lower of the two currents/voltages. This is because a higher current/voltage is likely to be on a higher voltage and to generate greater electromagnetic interference than a lower current/voltage. Therefore, it may be appropriate to carry out fewer functions in the location of higher electromagnetic interference and to carry out more functions in the location on low voltage, and of lower electromagnetic interference.

In a second option, instead of sending data from a one sensing module to the other, all time-stamped data may be sent for processing from the sensing modules to a processor independent of the sensing modules, such as an edge gateway device 600, a mobile device 370, or to the cloud server 360 for processing.

Returning to FIG. 5, the aggregated data is used in the calculation of current/voltage transformer ratio error ε_{ctx}/εᵥₜₓ and current/voltage transformer phase displacement error φ_{ctx}/φᵥₜₓ.

Calculation of the current/voltage transformer ratio error ε_{CTx}/ε_{VTx} and current/voltage transformer phase displacement error φ_{CTx}/φ_{VTx} also requires additional information related to the type of test. This information may be provided by a user, perhaps using a mobile device 370 as shown in FIG. 2 (current) or FIG. 3 (voltage). The information provided by the user may be provided back to the sensing modules as well as onward to a processor.

This information will include the details of the current/voltage transformer under test and details of the type of test.

For a current transformer, this information may comprise:
k_{nCTx}—rated transformation ratio of the current transformer under test
kₙₛ—rated transformation ratio of the sensor
measurement type, including:
   number of measurements,
   time interval of measurements,
   mode of measurement (slow/fast)
      k_{nCTtx} and kₙₛ are used to select the appropriate calibration table as well as for calculating of ε_{CTx} and φ_{CTx}.

Current ratio error ε is defined as:

$$ε = \frac{{k}_{n} * {I}_{s} - {I}_{p}}{{I}_{p}} 100 ( \% ) \qquad Equation 1$$

Voltage phase displacement error φ is defined as:

$$φ = 2 π f ( {t}_{0 s} - {t}_{0 p} ) \qquad Equation 2$$

where:
kₙ is rated transformation ratio (kₙ=Iₚₙ/Iₛₙ),
Iₚₙ, Iₛₙ, are rated values of the primary and secondary currents, respectively,
Iₚ, Iₛ are effective values (true RMS) of primary and secondary current, respectively,
f is fundamental power frequency of the current in the network (50 Hz or 60 Hz),
t₀ₚ and t₀ₛ, are successive zero crossing time (point) of primary and secondary current, respectively.

$$i = \frac{{I}_{p}}{{I}_{pn}} ( r . u . ) relative current$$

Error compensation and correction may also be performed (in the FIG. 5 embodiment this is performed on the cloud server 360), as explained further below.

For a voltage transformer, the information may comprise:
k_{nVTx}—rated transformation ratio of the voltage transformer under test
kₙₛ—rated transformation ratio of the sensor measurement type, including:
   number of measurements,
   time interval of measurements,
   mode of measurement (slow/fast)
      k_{nVTx} and kₙₛ are used to select the appropriate calibration table as well as for calculating of ε_{VTx} and φ_{VTx}.
      Voltage ratio error ε is defined as:

$$ε = \frac{{k}_{n} * {V}_{s} - {V}_{p}}{{V}_{p}} 100 ( \% ) \qquad Equation 3$$

Voltage phase displacement error φ is defined as:

$$φ = 2 π f ( {t}_{0 s} - {t}_{0 p} ) \qquad Equation 4$$

where:
kₙ is rated transformation ratio (kₙ=VₚₙVₛₙ,
Vₚₙ, Vₛₙ are rated values of the primary and secondary voltages, respectively,
Vₚ, Vₛ are effective values (true RMS) of primary and secondary voltage, respectively,
f is fundamental power frequency of the voltage in the network (50 Hz or 60 Hz),
t₀ₚ and t₀ₛ are successive zero crossing time (point) of primary and secondary voltage, respectively.

$$v = \frac{{V}_{p}}{{V}_{pn}} ( r . u . ) relative voltage$$

Error compensation and correction may also be performed on the sensed data (in the FIG. 5 embodiment this is performed in the cloud server 360) to account for known inaccuracies in the sensing modules, as explained further below.

FIG. 4 shows the four sensing modules (upstream current sensing module 330, downstream current sensing module 340, upstream voltage sensing module 430 and downstream voltage sensing module 440) in situ to perform measurements on the substation 200.

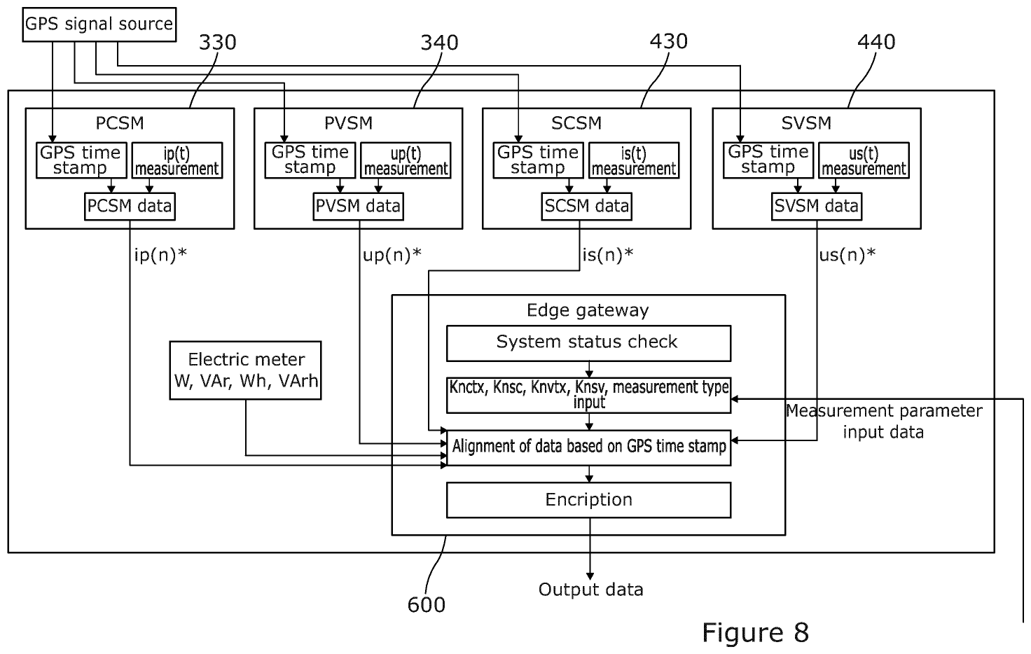

FIG. 8 shows how data derived from the four sensing modules (330, 340, 430, 440) shown in FIG. 4 are transmitted, together with data from the electricity meter 510, for onward calculations.

A further application of the data derived from the sensing modules may be for calculating active and reactive power data. Another application may be for calculating active and reactive energy data.

Active and reactive electric power, P and Q, respectively, are calculated using the following equations:

$$P = U * I * cos ( θ ) \qquad Equation 5$$

$$Q = U * I * sin ( θ ) \qquad Equation 6$$

where:
U=RMS value of voltage
I=RMS value of current
cos (θ)=the load power factor
   (θₚ=angle between primary current and primary voltage
   θₛ=angle between secondary current and secondary voltage)

Active and reactive electric energy, E_{Wh} and E_{VArh}, respectively, are then calculated as follows:

$${E}_{Wh} = P * Δ t \qquad Equation 7$$

$${E}_{VArh} = Q * Δ t \qquad Equation 8$$

where Δt is the time interval for which energy is calculated.

By using the approach of the present method, it is not only possible to measure active and reactive energy and/or power but it is also possible to quantify, separately, errors in expected active and reactive energy/power data arising from the current transformer, the voltage transformer, and the energy meter used for metering and billing in electric power grid. Moreover, it is possible to determine these errors in real time, live line in real operating conditions (with real current, voltage and power factor), with real load of the secondary circuit of current and voltage transformers.

The total error (eₚ, e_{q}) in the measurement of the elapsed electric energy/power (active or reactive), measured by the indirect method, consists of three components: the measurement error of the current transformer (eₚ^{CTx}, e_{q}^{CTx}), the measurement error of the voltage transformer (eₚ^{VTx}, e_{q}^{VTx}) and the measurement error of the electric energy meter at the low voltage side (eₚ^{EM}, e_{q}^{EM}).

This is expressed in the following equations.

The total error of active electric power measurement:

$${e}_{p} = {e}_{p}^{CTx} + {e}_{p}^{VTx} + {e}_{p}^{EM} \qquad Equation 9$$

The total error of reactive electric power measurement:

$${e}_{q} = {e}_{q}^{CTx} + {e}_{q}^{VTx} + {e}_{q}^{EM} \qquad Equation 10$$

Where:
eₚ^{CTx}=error of active power caused by current transformer under test
e_{q}^{CTx}=error of reactive power caused by current transformer under test
eₚ^{VTx}=error of active power caused by voltage transformer under test
e_{q}^{VTx}=error of reactive power caused by voltage transformer under test
eₚ^{EM}=error of active power caused by electric energy meter under test and
e_{q}^{EM}=error of reactive power caused by electric energy meter under test

The assessment of the total error may be carried out by four separate processes, each of which uses data from some of the sensing modules and from others of the processes.

The four processes are high voltage data processing, current transformer data processing, voltage transformer data processing and low voltage data processing.

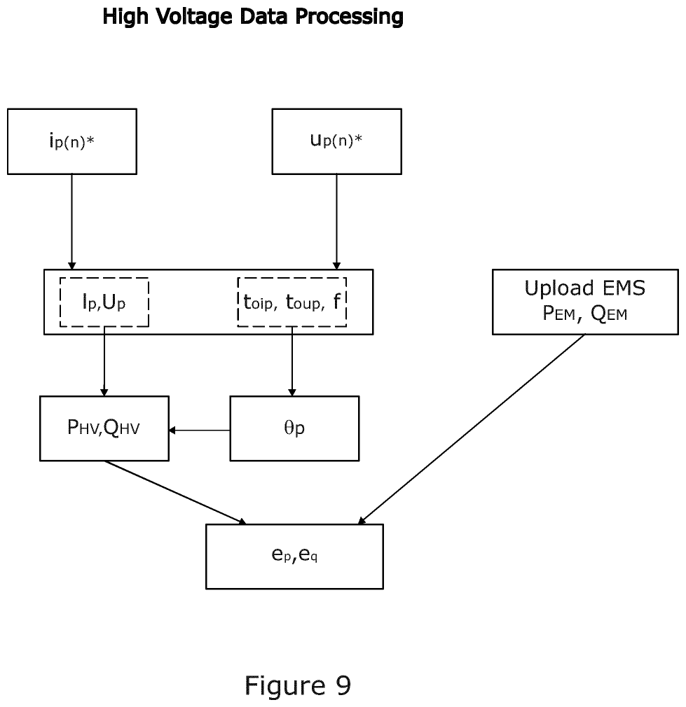

FIG. 9 shows a schematic representation of high voltage data processing.

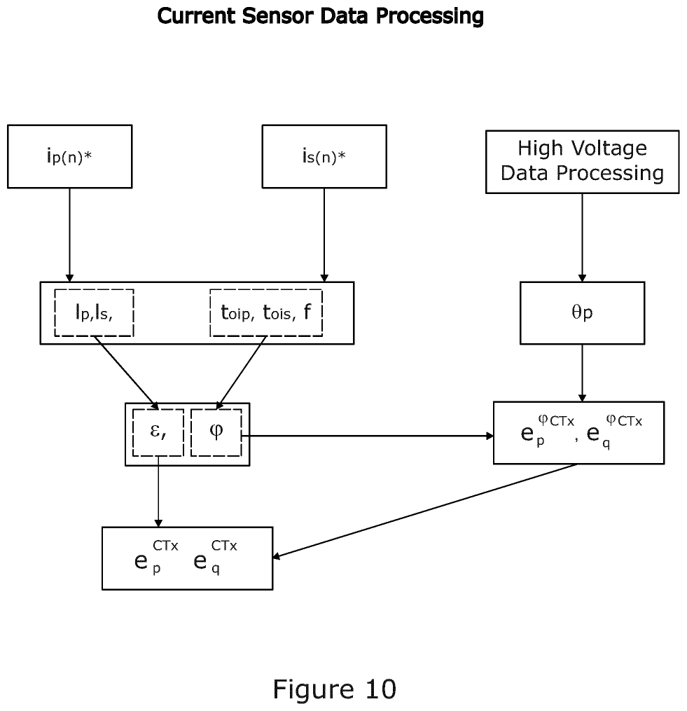

FIG. 10 shows a schematic representation of current transformer data processing.

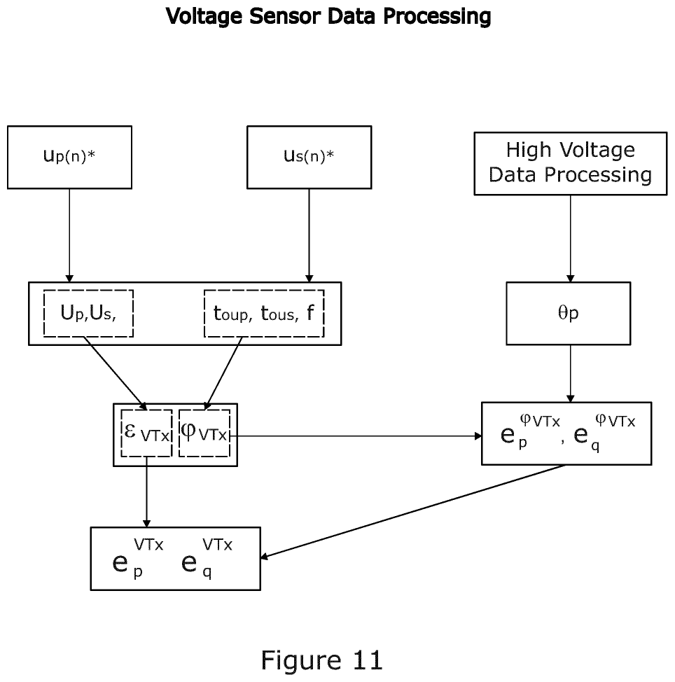

FIG. 11 shows a schematic representation of voltage transformer data processing.

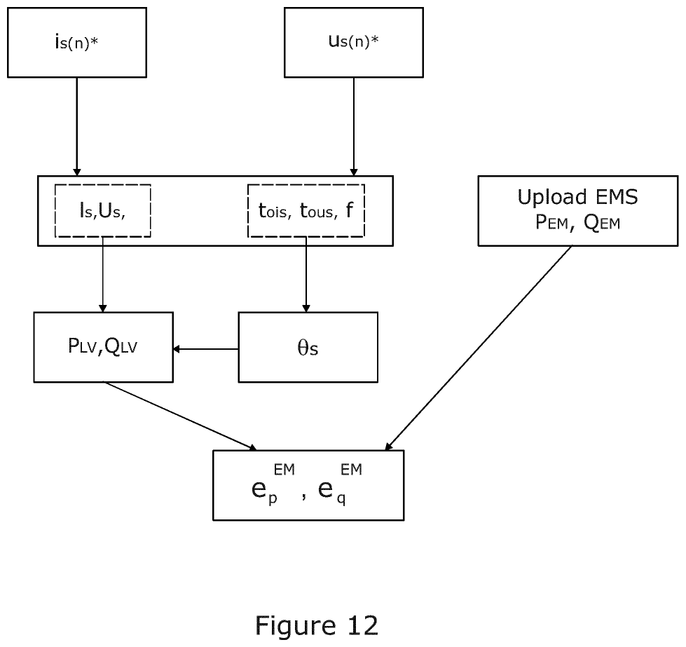

FIG. 12 shows a schematic representation of low voltage data processing.

### High Voltage Data Processing (FIG. 9)

The high voltage data processing serves to determine the total error in the calculation of electric power on MV and HV by comparing the results with the measured values shown by the electric power meter at low voltage.

As a result, the total error in the measurement of the active or reactive electric power is determined as ep (%) and e_{q} (%), respectively.

The high voltage data processing uses Equation 5 and Equation 6 to determine at the High Voltage side the active and reactive electric power, P_{HV} and Q_{HV}.

Thus, using digitalized time synchronized primary current data values, iₚ₍ₙ₎*, and digitalized time synchronized primary voltage data values, uₚ₍ₙ₎*, from the PCSM and PVSM, respectively, and uploading the electric meter indication at LV the high voltage data processing calculates eₚ (%), e_{q} (%). (Note that the * in iₚ₍ₙ₎* and uₚ₍ₙ₎* indicates that these are the digitalized values for their respective analogue counterparts, iₚ₍ₙ₎ and uₚ₍ₙ₎ as obtained by the sensors.)

High voltage data processing measures:
RMS values of Iₚ and Uₚ,
Zero crossings t₀ᵢₚ and t₀ᵤₚ then calculates θₚ=w*Δt=2πf*(t₀ᵢₚ−t₀ᵤₚ)

Then, using equations 5 and 6:

$${P}_{HV} = Up * Ip * cos ( {θ}_{p} ) \\ {Q}_{HV} = Up * Ip * sin ( {θ}_{p} )$$

Separately, the values for active and reactive power measured by the electric energy meter at LV (P_{EM} and Q_{EM}, respectively) are obtained from the LV electric energy meter.

Then the total errors of electric power measurement are calculated as follows:

The total error of active electric power measurement

$${e}_{p} ( \% ) = \frac{{P}_{EM} - {P}_{HV}}{{P}_{HV}} * 100 ,$$

The total error of reactive electric power measurement

$${e}_{q} ( \% ) = \frac{{Q}_{EM} - {Q}_{HV}}{Q} * 100.$$

### Current Transformer Data Processing (FIG. 10)

The current transformer data processing serves to determine the amplitude error, ε_{CTx}, and the phase displacement error, φ_{CTx}, of the current transformer under test. As a result, the error component in the measurement of the active and reactive electric power, eₚ^{CTx} and e_{q}^{CTx}, caused by the current transformer can be calculated.

Thus, using digitalized time synchronized primary current data values, iₚ₍ₙ₎*, and digitalized time synchronized secondary current data values, iₛ₍ₙ₎*, from the PCSM and SCSM, and uploading the load power factor θₚ from the high voltage data processing, the current transformer data processing calculates eₚ^{CTx}, e_{q}^{CTx}.

The current transformer data processing takes as an input the values for ratio error, ε_{CTx}(%), and phase displacement error, φ_{CTx}(min), of the current transformer. (As explained in more detail below, the values may be measured values corrected to compensate for errors in the current sensing modules. The error compensation may be obtained through calibration of the current sensing modules, as explained elsewhere.)

The error component, eₚ^{CTx}, in the measurement of the active electric power caused by the current transformer under test is then calculated as follows:

$${e}_{p}^{CTx} ( \% ) = {ε}_{CTx} ( \% ) + {e}_{p}^{φ CTx} ( \% ) \\ where {e}_{p}^{φ CTx} ( \% ) = \frac{cos ( θ p + {φ}_{CTx} ) - cos ( θ p )}{cos ( θ p )} * 100$$

The error component, e_{q}^{CTx}, in the measurement of the reactive electric power caused by the current transformer under test is then calculated as follows:

$${e}_{q}^{CTx} ( \% ) = {ε}_{CTx} ( \% ) + {e}_{q}^{φ CTx} ( \% ) \\ where {e}_{q}^{φ CTx} ( \% ) = \frac{sin ( θ p + {φ}_{CTx} ) - sin ( θ p )}{sin ( θ p )} * 100$$

### Voltage Transformer Data Processing (FIG. 11)

The voltage transformer data processing serves to determine the amplitude error E_{VTx} and the phase displacement error φ_{VTx} of the voltage transformer under test. As a result, the error component in the measurement of the active and reactive electric power caused by tested voltage transformer eₚ^{VTx} and e_{q}^{VTx}, respectively, can be calculated.

Thus, using digitalized time synchronized primary voltage data values, uₚ₍ₙ₎*, and digitalized time synchronized secondary voltage data values, uₛ₍ₙ₎*, from the PVSM and SVSM, respectively, and uploading the load power factor θₚ from the high voltage data processing, the voltage transformer data processing calculates eₚ^{VTx}, e_{q}^{VTx} (%).

The voltage transformer data processing takes as an input the values for ratio error, ε_{VTx}(%), and phase displacement error, Φ_{VTx}(min), of the voltage transformer. (As explained in more detail below, the values may be measured values corrected to compensate for errors in the current sensing modules. The error compensation may be obtained through calibration of the current sensing modules, as explained elsewhere.)

The error component, eₚ^{VTx}, in the measurement of the active electric power caused by the voltage transformer under test is then calculated as follows:

$${e}_{p}^{VTx} ( \% ) = {ε}_{VTx} ( \% ) + {e}_{p}^{φ VTx} ( \% ) \\ where {e}_{p}^{φ VTx} ( \% ) = \frac{cos ( θ p - {φ}_{VTx} ) - cos ( θ p )}{cos ( θ p )} * 100$$

The error component, e_{q}^{VTx}, in the measurement of the reactive electric power caused by the voltage transformer under test is then calculated as follows:

$${e}_{q}^{VTx} ( \% ) = {ε}_{VTx} ( \% ) + {e}_{q}^{φ VTx} ( \% ) \\ where {e}_{q}^{φ VTx} ( \% ) = \frac{sin ( θ p - {φ}_{VTx} ) - sin ( θ p )}{sin ( θ p )} * 100$$

### Low Voltage Data Processing (FIG. 12)

The low voltage data processing serves to determine the error in the calculation of electric power on LV by comparing the results with the measured values shown by the electric power meter at low voltage.

As a result, the error in the measurement of the active or reactive electric power caused by electric meter under test is determined as eₚ^{EM} (%) and e_{q}^{EM} (%), respectively.

The low voltage data processing uses Equation 5 and Equation 6 to determine at the Low Voltage side the active and reactive electric power, P_{LV} and Q_{LV}.

Thus, using digitalized time synchronized secondary current data, iₛ₍ₙ₎*, and digitalized time synchronized secondary voltage data values, uₛ₍ₙ₎*, from the SCSM and SVSM, respectively, and uploading the electric meter indication at LV the low voltage data processing calculates eₚ^{EM} (%), e_{q}^{EM} (%).

Low voltage data processing measures:
RMS values of Iₛ and Uₛ
Zero crossings t₀ᵢₛ, and t₀ᵤₛ
then calculates θₛ=w*Δt=2πf*(t₀ᵢₛ−t₀ᵤₛ)

Then, using equations 5 and 6, the active and reactive electric energy at the low voltage side, P_{LV} and Q_{LV}, respectively, are calculated as follows:

$${P}_{LV} = {k}_{nVTx} * {U}_{s} * {k}_{nCTx} * {I}_{s} * cos ( {θ}_{s} ) \\ {Q}_{LV} = {k}_{nVTx} * {U}_{s} * {k}_{nCTx} * {I}_{s} * sin ( {θ}_{s} )$$

Separately, the values for active and reactive power measured by the electric energy meter at LV (P_{EM} and Q_{EM}, respectively) are obtained from the LV electric energy meter.

Then the error components resulting from the energy meter are calculated for active energy, eₚ^{EM}, and reactive energy, e_{q}^{EM}, as follows:

$${e}_{p}^{EM} ( \% ) = \frac{{P}_{EM} - {P}_{LV}}{{P}_{LV}} * 100 \\ {e}_{q}^{EM} ( \% ) = \frac{{Q}_{EM} - {Q}_{LV}}{{Q}_{LV}} * 100$$

### Hardware

Aspects of the hardware of the primary/upstream current sensing module (PCSM) 330, the secondary/downstream sensing module (SCSM) 340, the primary/upstream voltage sensing module (PVSM), 430 and the secondary/downstream voltage sensing module (SVSM) 440 are now described.

FIGS. 13 and 14 show a high level schematic view of the features of the primary and secondary current sensing modules 330, 340 respectively. Each of the primary current sensing module 330 and the secondary current sensing module 340 may comprise a sensor 331, a measuring unit 332, a battery 333, a control unit 334, a memory unit 335 and an interface unit 336. The interface unit 336 may comprise a GNSS interface apparatus 337, a radio frequency (RF) interface apparatus 338 and a WiFi interface apparatus 339. The GNSS interface apparatus 337 may be configured to receive the GNSS data, including the time stamp data. The sensor 331 may be configured to obtain analogue current data. The measuring unit 332 may be configured to convert analogue current data to digital current data. The control unit 334 may be configured to ensure that each current data point is attributed with the time-stamp provided via the GNSS interface apparatus 337. The RF interface apparatus 338 and/or the WiFi apparatus interface 339 may be configured to transmit/receive the time-stamped current data to/from the one sensing module (e.g. primary/secondary sensing module) from/to the other current sensing module (e.g. secondary/primary sensing module) and/or to the edge gateway device 600 and/or to the cloud server 360.

In some embodiments, aggregation and alignment of time-stamped primary and secondary current data might take place in one of the PCSM and the SCSM. Alternatively, aggregation and alignment of time-stamped primary and secondary current data may be carried out externally, for example in a so-called edge gateway device 600 as shown in FIG. 4 and FIG. 8.

FIGS. 15 and 16 show a high level schematic view of the features of the primary and secondary voltage sensing modules 430, 440 respectively. Each of the primary voltage sensing module 430 and the secondary voltage sensing module 440 may comprise a sensor 441, a measuring unit 442, a battery 443, a control unit 444, a memory unit 445 and an interface unit 446. The interface unit 446 may comprise a GNSS interface apparatus 447, a radio frequency (RF) interface apparatus 448 and a WiFi interface apparatus 449. The GNSS interface apparatus 447 may be configured to receive the GNSS data, including the time stamp data. The sensor 441 may be configured to obtain analogue voltage data. The measuring unit 442 may be configured to convert analogue voltage data to digital voltage data. The control unit 444 may be configured to ensure that each voltage data point is attributed with the time-stamp provided via the GNSS interface apparatus 447. The RF interface apparatus 448 and/or the WiFi apparatus interface 449 may be configured to transmit/receive the time-stamped voltage data to/from the one sensing module (e.g. primary/secondary sensing module) from/to the other voltage sensing module (e.g. secondary/primary sensing module) and/or to the edge gateway device 600 and/or to the cloud server 360.

In some embodiments, aggregation and alignment of time-stamped primary and secondary current data might take place in one of the PVSM 430 and the SVSM 440. Alternatively, aggregation and alignment of time-stamped primary and secondary current data may be carried out externally, for example in a so-called edge gateway device 600 as shown in FIG. 4 and FIG. 8.

Note that while aggregation and alignment of time-stamped current and voltage data streams may be performed anywhere (e.g. remotely in the cloud), that is not the case for time stamping of the current or the voltage data. In particular, each of the primary and secondary current and voltage sensing modules 330 340, 430, 440 has its own GNSS interface apparatus 337, 447 and attribution of the time stamp to the current/voltage data is performed in the sensing module 330, 340, 430, 440 on which the current/voltage sensing is performed rather that remotely. This maximises accurate time stamping of each current/voltage data point.

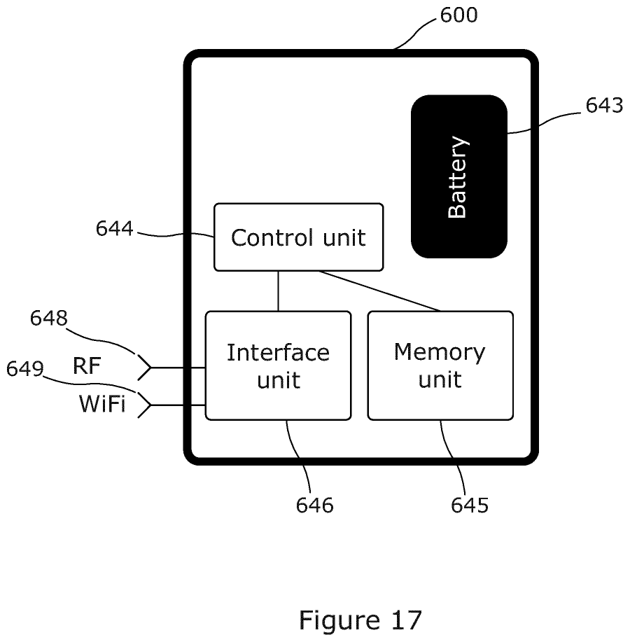

FIG. 17 shows an edge gateway device 600 which may comprise a processor configured to aggregate and align data provided by the primary current sensing module 330, the secondary current sensing module 340, the primary voltage sensing module 430 and the secondary voltage sensing module 440. The edge gateway device 600 may be configured to package that data, or data derived from that data, for onward transmission to, for example, a cloud server 360.

The edge gateway device 600 comprises a battery 643, a control unit 644, a memory unit 645 and an interface unit 646. The interface unit 646 comprises a radio frequency (RF) interface apparatus 648 and a WiFi apparatus interface 649. One or both of the radio frequency (RF) interface apparatus 648 and a WiFi apparatus interface 649 may be configured to receive time stamped data from any of the primary current sensing module 330, the secondary current sensing module 340, the primary voltage sensing module 430 and the secondary voltage sensing module 440. The WiFi apparatus interface 649 may be configured to receive data from a user and/or from a server and may also be configured to transmit data to the user and/or to a server.

### Calibration of a Pair of Primary Current and Secondary Current Sensing Modules

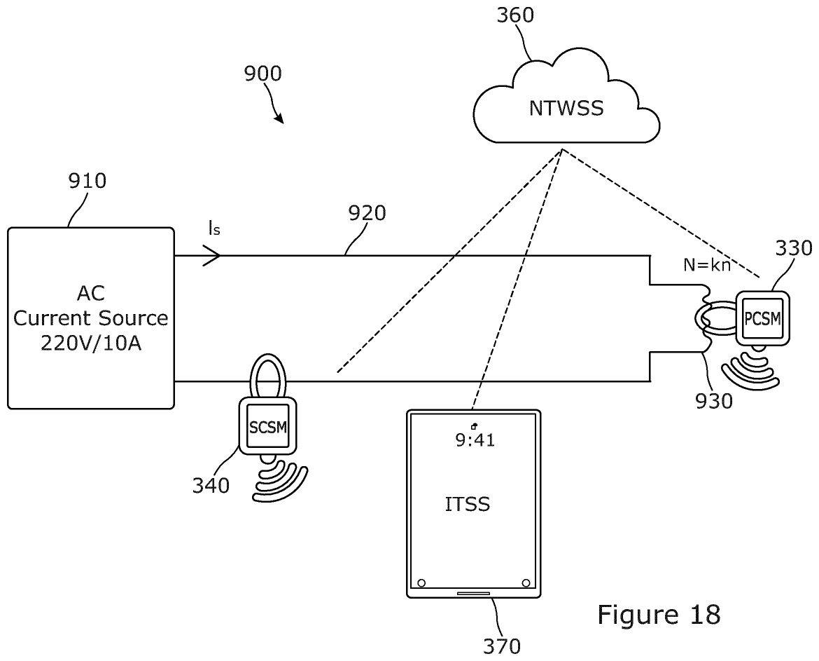

FIG. 18 shows a calibration rig that may be used to calibrate a pair of primary current sensing module and secondary current sensing module. Given the high degree of precision required of the testing method, it is necessary to ensure that the sensing apparatus is correctly calibrated.

The calibration rig comprises an AC current source 910 and a series circuit 920 comprising a coil 930. The calibration process requires the primary current sensing module 330 to sense the current in the coil 930 and requires the secondary current sensing module 340 to be used simultaneously to sense the current elsewhere in the circuit 320. In this way, errors that derive from the measurement apparatus can be quantified and removed from the calculation of errors in the behaviour of the current transformer under test.

The coil (N=Kn) in FIG. 18 should ensure that the current flowing through the primary current sensing module is kn times greater than the current flowing through the secondary current sensing module.

So the coil with N=Kn turns simulates CTx with kn transformation ratio. The coil with N=kn acts as a standard transformer and may have a minor ratio error and a minor phase displacement error.

When the calibration is performed on the coil with N=kₙ turns, which has minor standard transformer errors, the errors of the test system are recorded. These errors are transmitted to a Software Error Compensation and Correction (SECC) block which may be located on the cloud server 360, as shown in FIG. 1. The SECC then uses these error values when testing CTx with kn transformation ratio in real operating conditions to compensate for the known errors.

In a little more detail, as part of the calibration process, a series of timestamped upstream current data points and a series of timestamped downstream current data points are obtained in order to populate a calibration table (LUT-look up table) comprising rows and columns. The number of columns may be equal to the number of calibration points derived during the calibration process, wherein each calibration point may be at a different relative current in accordance with the current supplied by the AC current source 910. Each calibration point K, from the first (1) to the last (n) contains three data points: relative current at calibrated point k (iₖ), ratio error of the system at calibration point k (εₖ), phase displacement error of the system at calibration point k (φₖ), respectively for each k∈(1, n), a set of calibration values (iₖ, εₖ, φₖ) is formed.

The number of calibration points (n) and the values of relative currents (iₖ) may be arbitrarily chosen. Preferred values for n may be n=5, 10, 15, respectively, and iₖ values are minimum 0.05 and maximal 1.5 of the rated primary current.

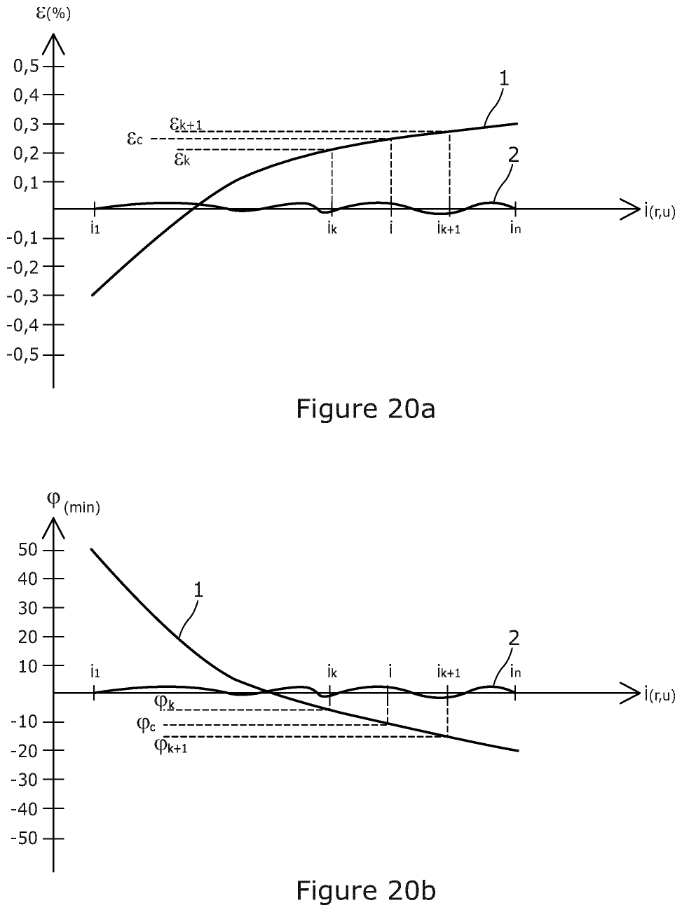

Compensation values are determined on the basis of a linear interpolation between two known successive calibration points from the calibration table as shown in FIG. 20.

### Calibration of a Pair of Primary Voltage and Secondary Voltage Sensing Modules

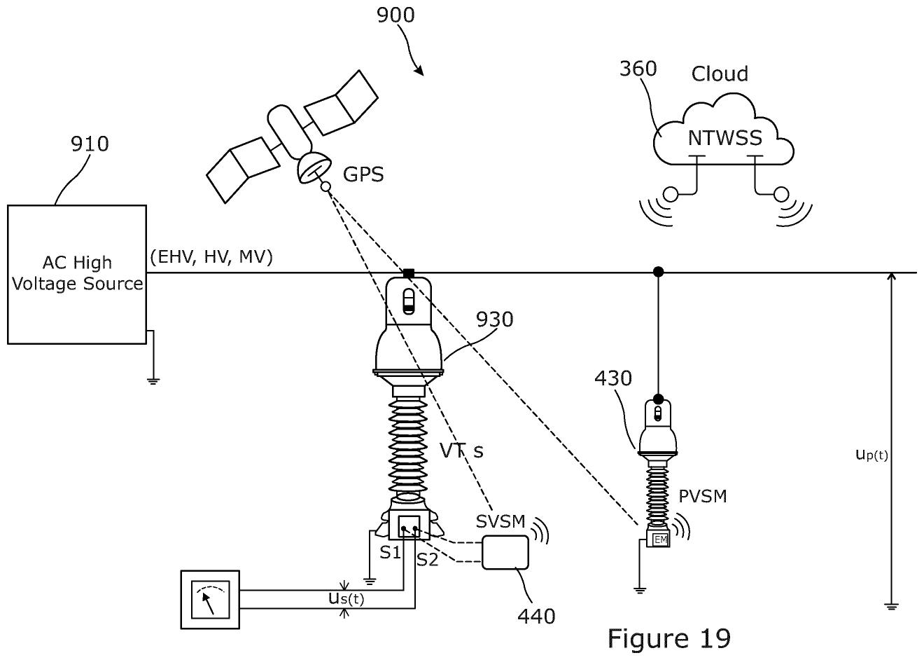

FIG. 19 shows a calibration rig that may be used to calibrate a pair of primary voltage and secondary voltage sensing modules 430, 440. Given the high degree of precision required of the testing method, it is necessary to ensure that the sensing apparatus is correctly calibrated.

The calibration circuit 900 comprises an AC high voltage source 910 and a high voltage conductor 920 comprising a standard high voltage transformer (VTs) 930 having a transformation ratio Kₙ. The calibration process requires the primary voltage sensing module 430 to sense the voltage at the high voltage conductor 920 and requires the secondary voltage sensing module 440 to be used simultaneously to sense the voltage at the low voltage side of the standard high voltage transformer 930.

The standard high voltage transformer VTs 930 is selected for having the same rated ratio, Kₙ, as the rated ratio Knvtx of the transformer VTx 400 to be tested. However, the standard high voltage transformer VTs 930 is selected for its minor ratio and phase displacement errors, with accuracy class at least 0.05%. Thus, when the calibration is performed, errors in the sensing are attributed to the primary voltage sensing module 430 and the secondary voltage sensing module 440, rather than to the standard high voltage transformer VTs 930. The errors determined in this way are transmitted to a Software Error Compensation and Correction (SECC) block which may be located on the cloud server 360, as shown in FIG. 1.

Then, when the primary voltage sensing module 430 and the secondary voltage sensing module 440 are used to test a voltage transformer (VTx) in real operating conditions, the errors derived from the calibration process are effectively removed by the SECC from the measured data in order to provide a high degree of accuracy in measuring the ratio and phase displacement errors (and hence the transformation ratio Kₙᵥₜₓ) of the VTx.

In more detail, the calibration process involves obtaining a series of timestamped upstream voltage data points and a series of timestamped downstream voltage data points for VTs so as to populate a calibration table (LUT-look up table) comprising rows and columns. The number of columns may be equal to the number of calibration points derived during the calibration process, wherein each calibration point may be at a different relative voltage in accordance with the voltage supplied by the AC high voltage source 910. Each calibration point K, from the first (1) to the last (n) contains three data points: relative voltage at calibrated point k (uₖ), ratio error of the system at calibration point k (εₖ), phase displacement error of the system at calibration point k (φₖ), respectively for each k∈(1, n). In this way, a set of calibration values (uₖ, εₖ, φₖ) is formed.

The number of calibration points (n) and the values of relative voltages (uₖ) may be arbitrarily chosen. Preferred values for n may be n=5, 10, 15, respectively, and uₖ values are minimum 0.1 and maximal 1.2 of the rated primary voltage.

Once the primary voltage sensing module 430 and the secondary voltage sensing module 440 are in their respective positions on either side of the voltage transformer VTx 400 under test, the timestamped upstream and downstream voltage data points are derived from the primary voltage sensing module 430 and the secondary voltage sensing module 440, and the measured ratio error and phase displacement error and relative voltage are calculated using the uncompensated values.

Next, the calibration data derived via the calibration process is used to remove the known errors.

In this way, highly accurate ratio and phase displacement errors for the voltage transformer under test may be obtained.

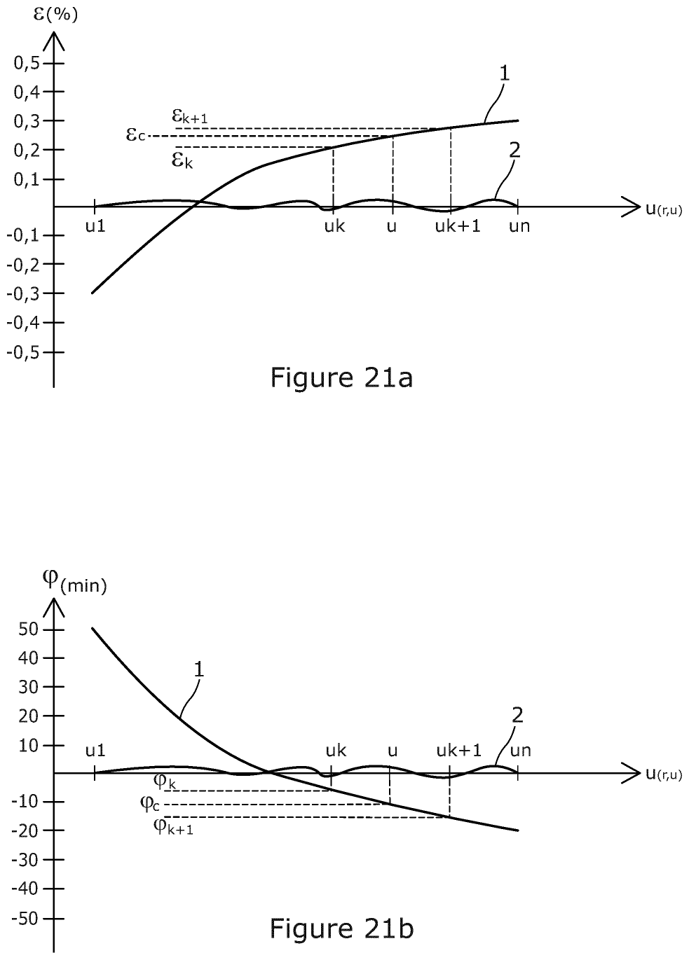

Compensation values are determined on the basis of a linear interpolation between two known successive calibration points from the calibration table as shown in FIG. 21.

Linear Interpolation Approach for Obtaining Compensation Values from the Calibration Data

An example of a calibration table (in this case for voltage sensors, but the same principles apply for current sensors) is provided in Table 1 showing five calibration points:

TABLE 1

| uₖ [r.u.] | uₛ [V] | εₖ [%] | φₖ [min] |
|---|---|---|---|
| 0.50 | 50 | 0.19 | −8.2 |
| 0.60 | 60 | 0.23 | −14.8 |
| 0.80 | 80 | 0.31 | −22.6 |
| 1.00 | 100 | 0.35 | −27.5 |
| 1.20 | 120 | 0.39 | −29 |

What follows is an explanation of how the calibration values may be used to compensate for and correct for the known errors.

Compensation values εₑ and φ_{c} for an arbitrary relative value of the primary voltage (u=Up/Upn) are determined on the basis of a linear interpolation between two known successive calibration points from the calibration table (k and k+1) as shown on FIGS. 21a and 21b.

The real relative value of the primary voltage (u=Up/Upn) may be uₖ₊₁, ≥u≥uₖ, where k is k-th calibration point.

Using linear interpolation as shown in FIGS. 21a and 21b, ε_{c} and φ_{c} are calculated as follows:

$$for {u}_{k + 1} > u > {u}_{k} ; {ε}_{c} = {ε}_{k} + \frac{{ε}_{k + 1} - {ε}_{k}}{{u}_{k + 1} - {u}_{k}} ( u - {u}_{k} ) ; \\ {φ}_{c} = {φ}_{k} + \frac{{φ}_{k + 1} - {φ}_{k}}{{u}_{k + 1} - {u}_{k}} ( u - {u}_{k} ) ; \\ for u = {u}_{k} ; {ε}_{c} = {ε}_{k} ; {φ}_{c} = {φ}_{k} , \\ for u = {u}_{k + 1} ; {ε}_{c} = {ε}_{k + 1} ; {φ}_{c} = {φ}_{k + 1}$$

If u<u₁ linear extrapolation uses calibration points u₁ and u₂.

If u>uₙ linear extrapolation uses calibration points uₙ₋₁ and uₙ.

$${ε}_{ctx} = {ε}_{m} - {ε}_{c} \\ {φ}_{ctx} = {φ}_{m} - {φ}_{c}$$

An exemplary data set for results of SECC is shown in Table 3:

TABLE 2

| u | Uₛ | εₘ | φₘ | ε_{c} | φ_{c} | ε_{VTx} | φ_{VTx} |
|---|---|---|---|---|---|---|---|
| [r.u.] | [V] | [%] | [min] | [%] | [min] | [%] | [min] |
| 0.55 | 55 | 0.22 | −12.6 | 0.21 | −11.5 | 0.01 | −1.1 |
| 0.7 | 70 | 0.283 | −19.12 | 0.27 | −18.7 | 0.013 | −0.42 |
| 1.1 | 110 | 0.42 | −29.85 | 0.37 | −29 | 0.05 | −0.85 |

where:
εₘ and φₘ—measured values of ratio and phase displacement error,
ε_{c} and φ_{c}—compensation values of ratio and phase displacement error,
ε_{VTx} and φ_{VTx}—values of ratio and phase displacement error of voltage transformer under test.

In FIG. 21a, curve 1 represents the ratio error of the test system before calibration and curve 2 represents ratio error of the test system after calibration as a function of relative voltage.

In FIG. 21b, curve 1 represents the phase displacement error of the test system before calibration and curve 2 represents phase displacement error of the test system after calibration as a function of relative voltage.

The authors have demonstrated through a large number of experiments that the proposed methodology of calibration and correction improves the accuracy of the test system for the entire order of magnitude.

### Worked Example of Employing the Method for Determining the Components of Errors in Measuring Active and Reactive Power in Real Conditions in a 110 kV Substation

In a substation such as that shown in FIG. 4, the total errors in the measurement of active and reactive power are a combination of:
1. errors in the measurement of active and reactive power caused by the current transformer (eₚ^{CTx}, e_{q}^{CTx}),
2. errors in the measurement of active and reactive power caused by voltage transformer (eₚ^{VTx}, e_{q}^{VTx})
3. the errors in the measurement of active and reactive power caused by electric meter (eₚ^{EM}, e_{q}^{EM})

A real worked example was carried out by conducting the method of the disclosure on a 110 kV substation.

The characteristics of the equipment installed at the point where the measurement was performed were as follows:
electricity meter: accuracy class 0.1%
current transformer:
   nominal rated voltage Uₚₙ=110 kV, nominal rated current 400 A
   nominal rated transformation ratio

$${k}_{nCTx} = \frac{400 A}{1 A}$$

measuring core with accuracy class 0.5;
voltage transformer:
   nominal rated voltage Uₚₙ 110 kV
   nominal rated transformation ratio

$${k}_{nVTx} = \frac{\frac{110 kV}{\sqrt{3}}}{100 V} ,$$

measuring core with accuracy class 0.5;

Measurements were performed live line, in real operating conditions with real secondary burden, without unbundling of the conductors.

Table 3 shows the real measurement results derived from all of: high voltage data processing (FIG. 9), current transformer data processing (FIG. 10), voltage transformer data processing (FIG. 11) and low voltage data processing (FIG. 12). The first three pairs of rows identify the active and reactive power errors resulting from the current transformer, the voltage transformer and the electricity meter, respectively. The fourth pair of rows identify the total active and reactive power errors (eₚ and e_{q}), which is the sum of those resulting from the first three pairs of rows.

TABLE 3

| Iₚ | Iₛ | cos(θₚ) | ε_{CTx} | φ_{CTx} | eₚ^{φCTx} | e_{q}^{φCTx} | eₚ^{CTx} | e_{q}^{CTx} | Errors |
|---|---|---|---|---|---|---|---|---|---|
| [A | [A] | 0.8 | [%] | [min] | [%] | [%] | [%] | [%] | caused by |
| 200 | 0.50375 | | 0.75 | −45 | 0.97 | −1.75 | 1.72 | −1 | current |
| | | | | | | | | | transformer |
| Uₚ | Us | cos(θₚ) | ε_{VTx} | φ_{VTx} | eₚ^{φVTx} | e_{q}^{φVTx} | eₚ^{VTx} | e_{q}^{VTx} | Errors |
| [kV] | [V] | 0.8 | [%] | [min] | [%] | [%] | [%] | [%] | caused by |
| $\frac{110}{\sqrt{3}}$ | 100.5 | | 0.5 | +30 | 0.65 | −1.17 | 1.15 | −0.67 | voltage transformer |
| Uₛ [V] | Is | cos(θₛ) | P_{EM} | Q_{EM} | P_{LV} | Q_{LV} | eₚ^{EM} | e_{q}^{EM} | Errors |
| 100.5 | [A] | 0.813 | [MW] | [Var] | [MW] | [MVAr] | [%] | [%] | caused by |
| | 0.50375 | | 10.474 | 7.475 | 10.456 | 7.485 | 0.17 | −0.13 | electric |
| | | | | | | | | | meter |
| Uₚ | Iₚ | cos(θₚ) | P_{HV} | Q_{HV} | P_{EM} | Q_{EM} | eₚ | e_{q} | Total error |
| [kV] | [A] | 0.8 | [MW] | [MVAr] | [MW] | [MVAr] | [%] | [%] | (sum of all |
| $\frac{110}{\sqrt{3}}$ | 200 | | 10.161 | 7.621 | 10.474 | 7.475 | 3.04 | −1.8 | the above) |

It is immediately clear that the errors caused by the electricity meter (namely eₚ^{EM}=0.17% and e_{q}^{EM}=−0.13%) make a up a small proportion of the total error (namely eₚ=3.04% and e_{q}=−1.8%).

Thus, by this example it is immediately apparent that the approach of identifying only the errors in active and reactive power derived from the electricity meter—as is commonplace —is highly inaccurate. This is because much of the total error in the measurement of active and reactive power is outside the measurement capability of the existing approaches. By contrast, by adopting the method of the present disclosure, a significantly higher degree of accuracy in the quantification of errors in the active and reactive power can be achieved.

In financial terms, the difference between an error of 0.17% (=eₚ^{EM}) and an error of 3.04% (=eₚ) on an annual basis is significant. At an average market price of active electric energy of 100 Euro/MWh, a total error of 3% would equate to an annual price differential of 267,000 Euro.

### Three Phases

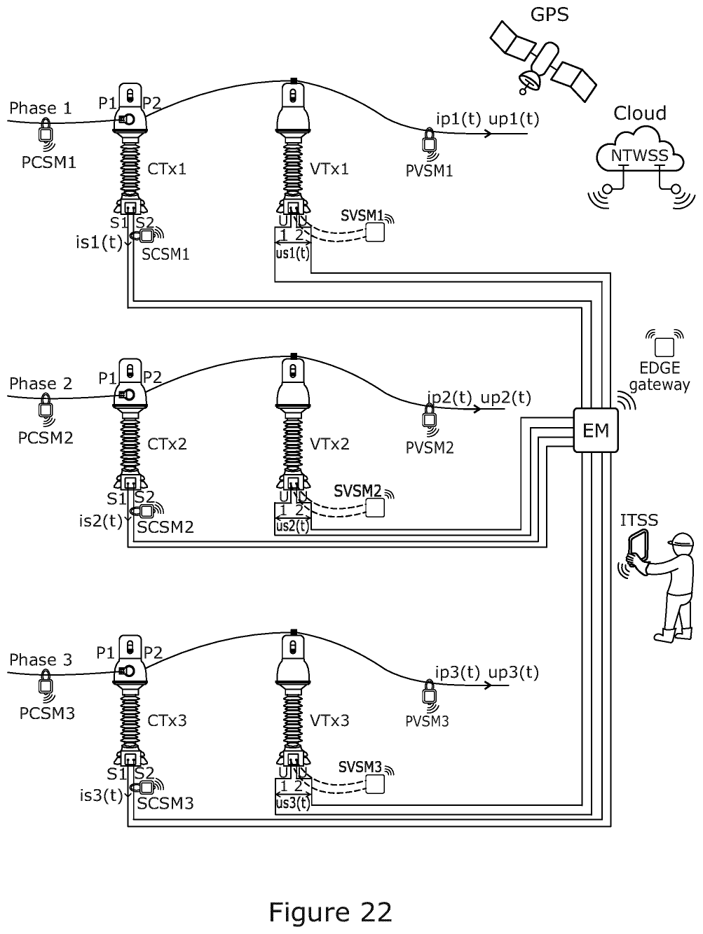

For simplicity and ease of understanding, the method of the present disclosure has so far been explained and illustrated only in respect of a single-phase electrical system. The method is equally applicable for three phase systems. FIG. 22 shows a potential implementation of the method in the context of a three phase system.

To perform three phase testing, either the method can be applied to each of the three phases sequentially. Alternatively, 12 sensing modules can be deployed (three primary current sensing modules, one for each phase; three secondary sensing modules, one for each phase; three primary voltage sensing modules, one for each phase; and three secondary voltage sensing modules, one for each phase). Each of the 12 sensing modules has its own means of receiving global navigation satellite system for time stamping its data.

A single device (e.g. a single edge gateway device) can be deployed to receive the data from all 12 sensing modules, and from the electric meter, and to perform the calculations as set out above but now in respect of all three phases.

### Other Applications of Active and Reactive Power Measurement

Although this disclosure focuses largely on the measurement of active and reactive power for the purposes of assessing errors in electricity metering, there are other uses for these data. For example, the data may be used for electricity quality analysis. Furthermore, the while the method may be employed as a one-off infrequent test to obtain an indication of current system errors, it is also possible that the method may be employed for assessing electrical parameters over days, weeks, months or longer.

### Alternatives

While the examples set out here relate to the transformation from higher to lower voltage, the method set out here is equally applicable to the transformation from lower to higher voltage.

While the calculations set out in detail here relate to calculation of active and reactive power (and active and reactive power errors), the methodology is equally applicable to the calculation of active and reactive energy (and active and reactive energy errors), by the simple addition of a time component to the calculations.

1. An online live line method of analysing properties of an electricity substation comprising a current transformer and a voltage transformer, the electricity substation configured to transform an upstream current and an upstream voltage into a downstream current and a downstream voltage, the method comprising:
using an upstream current sensor to obtain a series of upstream current data points during a first time period and attributing a time stamp provided by a first global navigation satellite system (GNSS) signal receiver to each one of the series of upstream current data points;
using a downstream current sensor to obtain a series of downstream current data points during the first time period and attributing a time stamp provided by a second GNSS signal receiver to each one of the series of downstream current data points;
using an upstream voltage sensor to obtain a series of upstream voltage data points during the first time period and attributing a time stamp provided by a third GNSS signal receiver to each one of the series of upstream voltage data points;
using a downstream voltage sensor to obtain a series of downstream voltage data points during the first time period and attributing a time stamp provided by a fourth GNSS signal receiver to each one of the series of upstream current data points;
calculating a current transformer phase displacement error between the time-stamped series of upstream current data points and the time-stamped series of downstream current data points;
calculating a current transformer ratio error by comparing a rated current ratio of the current transformer with a measured ratio determined using the time-stamped series of upstream current data points and the time-stamped series of downstream current data points;
calculating a voltage transformer phase displacement error between the time-stamped series of upstream voltage data points and the time-stamped series of downstream voltage data points;
calculating a voltage transformer ratio error by comparing a rated voltage ratio of the voltage transformer with a measured voltage ratio determined using the time-stamped series of upstream voltage data points and the time-stamped series of downstream voltage data points;
using the time-stamped series of upstream current data points and the time-stamped series of upstream voltage data points to produce calculated upstream active and reactive power data;
using the time-stamped series of downstream current data points and the time-stamped series of downstream voltage data points to produce calculated downstream active and reactive power data.

2. The method of claim 1 further comprising using:
the calculated current transformer phase displacement error; and
the calculated current transformer ratio error;
to calculate an error of active and reactive power measurement resulting from the current transformer.

3. The method of claim 1 further comprising using:
the calculated voltage transformer phase displacement error; and
the calculated voltage transformer ratio error;
to calculate an error of active and reactive power measurement resulting from the voltage transformer.

4. The method of claim 1 further comprising obtaining measured active and reactive power data from an electricity meter downstream of the electricity substation configured for metering power supplied by the substation.

5. The method of claim 4 further comprising using:
the calculated upstream active and reactive power data; and
the active and reactive power data from the downstream electricity meter;
to calculate a total error of active and reactive power measurement;
wherein optionally comprising using,
the calculated downstream active and reactive power data; and
the active and reactive power data from the downstream electricity meter;
to calculate an error component in active and reactive power measurement by the downstream electricity meter.

6. (canceled)

7. The method of claim 1 further comprising a calibration process carried out to quantify upstream current sensor errors, downstream current sensor errors, upstream voltage sensor errors and downstream voltage sensor errors,
wherein optionally:
time-stamped series of upstream current data points are adapted to compensate for the upstream current sensor errors;
time-stamped series of downstream current data points are adapted to compensate for the downstream current sensor errors;
time-stamped series of upstream voltage data points are adapted to compensate for the upstream voltage sensor errors; and
time-stamped series of downstream voltage data points are adapted to compensate for the downstream voltage sensor errors.

8. (canceled)

9. The method of claim 1 wherein the measured ratio is a ratio of:
a root mean square value of the series of upstream data points; to
a root mean square value of the series of downstream data points.

10. The method of claim 1 wherein the current/voltage transformer phase displacement error is proportional to a time difference between at least one pair of successive zero crossings of time stamped upstream data and time stamped downstream data, wherein accuracy of time reference is less than 100 nanoseconds and preferably approximately 10 nanoseconds.

11. The method of claim 1 wherein each of the stream of upstream current or voltage data points and the stream of downstream current or voltage data points comprises at least 20,000 data points per AC cycle, preferably 40,000 data points per AC cycle.

12. The method of claim 1 wherein the electric substation is a three phase electric substation;
wherein the current transformer and the voltage transformer of claim 1 are a first phase current transformer and a first phase voltage transformer;
wherein the three phase electric substation comprises a second phase current transformer, a second phase voltage transformer, a third phase current transformer and a third phase voltage transformer;
wherein the method comprises deploying the method set out in claim 1 on each of the three phases, optionally simultaneously.

13. (canceled)

14. The method of claim 1 further comprising one or both of:
using the calculated upstream active and reactive power data to calculate upstream active and reactive energy data;
using the calculated downstream active and reactive power data to calculate downstream active and reactive energy data.

15. A kit of parts for carrying out the method of claim 1, the kit of parts comprising:
an upstream current sensor module comprising an upstream current sensor and a first global navigation satellite system (GNSS) signal receiver, wherein the upstream current sensor is configured to obtain a series of upstream current data points during a first time period and the first GNSS signal receiver is configured to attribute a time stamp to each one of the series of upstream current data points;
a downstream current sensor module comprising a downstream current sensor and a second GNSS signal receiver, wherein the downstream current sensor is configured to obtain a series of downstream current data points during a first time period and the second GNSS signal receiver is configured to attribute a time stamp to each one of the series of downstream current data points;
an upstream voltage sensor module comprising an upstream voltage sensor and a first global navigation satellite system (GNSS) signal receiver, wherein the upstream voltage sensor is configured to obtain a series of upstream voltage data points during a first time period and the first GNSS signal receiver is configured to attribute a time stamp to each one of the series of upstream voltage data points;
a downstream voltage sensor module comprising a downstream voltage sensor and a second GNSS signal receiver, wherein the downstream voltage sensor is configured to obtain a series of downstream voltage data points during a first time period and the second GNSS signal receiver is configured to attribute a time stamp to each one of the series of downstream voltage data points;
wherein optionally,
the upstream current sensor module further comprises an upstream current measuring unit configured to digitize the series of upstream current data points;
the downstream current sensor module further comprises a downstream current measuring unit configured to digitize the series of upstream current data points;
the upstream voltage sensor module further comprises an upstream voltage measuring unit configured to digitize the series of upstream voltage data points;
the downstream voltage sensor module further comprises a downstream voltage measuring unit configured to digitize the series of upstream voltage data points.

16. (canceled)

17. The kit of parts of claim 15 wherein each of the upstream current sensor module, the downstream current sensor module, the upstream voltage sensor module and the downstream voltage sensor module comprises wireless communication functionality for receiving instructions pertaining to a measurement to be performed and for transmitting the time stamped series of data points for onward processing.

18. The kit of parts of claim 15 wherein one of the upstream current sensor module and the downstream current sensor module receives the time stamped current data provided by the other of the upstream current sensor module and the downstream current sensor module and is configured:
to calculate a current transformer phase displacement error between the time-stamped series of upstream current data points and the time-stamped series of downstream current data points; and
to calculate a current transformer ratio error by comparing a rated current ratio of the current transformer with a measured ratio determined using the time-stamped series of upstream current data points and the time-stamped series of downstream current data points.

19. The kit of parts of claim 15 wherein one of the upstream voltage sensor module and the downstream voltage sensor module receives the time stamped voltage data provided by the other of the upstream voltage sensor module and the downstream voltage sensor module and is configured:
to calculate a voltage transformer phase displacement error between the time-stamped series of upstream voltage data points and the time-stamped series of downstream voltage data points; and
to calculate a voltage transformer ratio error by comparing a rated current ratio of the voltage transformer with a measured ratio determined using the time-stamped series of upstream voltage data points and the time-stamped series of downstream voltage data points.

20. The kit of parts of claim 15 further comprising a processor configured to receive:
the time stamped current data provided by the upstream current sensor module;
the time stamped current data provided by the downstream current sensor module;
the time stamped voltage data provided by the upstream voltage sensor module; and
the time stamped voltage data provided by the downstream voltage sensor module; and is configured to:
calculate a current transformer phase displacement error between the time-stamped series of upstream current data points and the time-stamped series of downstream current data points; and to
calculate a current transformer ratio error by comparing a rated current ratio of the current transformer with a measured current ratio determined using the time-stamped series of upstream current data points and the time-stamped series of downstream current data points;
calculate a voltage transformer phase displacement error between the time-stamped series of upstream voltage data points and the time-stamped series of downstream voltage data points; and to
calculate a voltage transformer ratio error by comparing a rated voltage ratio of the voltage transformer with a measured voltage ratio determined using the time-stamped series of upstream voltage data points and the time-stamped series of downstream voltage data points;
wherein optionally the processor is further configured to:
use the time-stamped series of upstream current data points and the time-stamped series of upstream voltage data points to produce calculated upstream active reactive power data;
use the time-stamped series of downstream current data points and the time-stamped series of downstream voltage data points to produce calculated downstream active and reactive power data.

21. (canceled)

22. The kit of parts of claim 15 wherein the processor is further configured to use the calculated current transformer phase displacement error and the calculated current transformer ratio error to calculate an error of active and reactive power measurement resulting from the current transformer and/or wherein the processor is further configured to use the calculated voltage transformer phase displacement error and the calculated voltage transformer ratio error to calculate an error of active and reactive power measurement resulting from the voltage transformer.

23. (canceled)

24. The kit of parts of 15 wherein the processor is further configured to obtain measured active and reactive power data from an electricity meter downstream of the electricity substation configured for metering power supplied by the substation.

25. The kit of parts of claim 24 wherein the processor is further configured to use the calculated upstream active and reactive power data and the active and reactive power data from the downstream electricity meter to calculate a total error of active and reactive power measurement and, optionally, wherein the processor is further configured to use the calculated downstream active and reactive power data and the active and reactive power data from the downstream electricity meter to calculate an error component in active and reactive power measurement by the downstream electricity meter.

26. The kit of parts of claim 15 wherein the processor is further configured to compensate for known errors in the measurements provided by the upstream current sensor module, the downstream current sensor module, the upstream voltage sensor module and the downstream voltage sensor module.
